(19) United States
(12) Patent Application Publication
(10) Pub. No.: US 2026/0231486 A1
(43) Pub. Date: Aug. 6, 2026

(54) INTEGRATED CIRCUIT DEVICES INCLUDING SELF-ALIGNED BACKSIDE CONTACT STRUCTURES AND METHODS OF FORMING THE SAME

(71) Applicant: Samsung Electronics Co., Ltd., Suwon-si (KR)

(72) Inventors: Sangshin Jang, Rexford, NY (US); Wonkeun Chung, Clifton Park, NY (US); Byounghoon Kim, Rexford, NY (US); Kang-ill Seo, Springfield, VA (US)

(21) Appl. No.: 19/265,399

(22) Filed: Jul. 10, 2025

Related U.S. Application Data
(60) Provisional application No. 63/750,350, filed on Jan. 28, 2025.

(51) Int. Cl. H10D 62/10; H10D 30/00; H10D 64/01; H10D 64/23; H10W 20/41

(52) U.S. Cl. CPC H10D 62/115; H10D 30/501; H10D 64/01; H10D 64/254; H10W 20/427

(57) ABSTRACT

An integrated circuit device includes a substrate, a source/drain region on the substrate, a gate structure on the substrate and adjacent to the source/drain region, a backside contact structure extending in the substrate and electrically connected to the source/drain region, and a spacer in the substrate and on a lower surface of the gate structure, the spacer adjacent to the backside contact structure.

### RELATED APPLICATIONS

The present application claims the benefit of U.S. Provisional Patent Application Serial No. 63/750,350, entitled “INTEGRATED CIRCUIT DEVICES INCLUDING BACKSIDE POWER DELIVERY NETWORK STRUCTURES AND METHODS OF FORMING THE SAME,” filed on January 28, 2025, with the United States Patent and Trademark Office, the disclosure of which is hereby incorporated by reference herein in its entirety.

### TECHNICAL FIELD

The present disclosure generally relates to the field of integrated circuit devices and, more particularly, to integrated circuit devices including backside contact structures and methods of forming the same.

### BACKGROUND

Integrated circuit devices, chips, and/or blocks may receive power and data signals from one or more external sources (e.g., a power source and a data source). Some integrated circuit devices may receive power and data signals via frontside conductive structures, which may provide power delivery networks. For example, an integrated circuit device may include a frontside power delivery network (FSPDN) structure having one or more components that are formed during the back-end-of-line (BEOL) portion of device fabrication, and conductive structures for data signals may be on the same side of the integrated circuit device as the FSPDN structure. Integrated circuit devices may include various transistor structures, including, for example, two-dimensional (2D) planar structures, fin field-effect transistors (FinFETs), gate-all-around (GAA) transistors, multi-bridge channel FETs (MBCFETs^{TM}), and stacked transistors (e.g., three-dimensional (3D) stacked transistors).

More recently, backside power delivery network (BSPDN) structures, in which a backside of an integrated circuit device is used as a power delivery network, have also been developed. In a BSPDN structure, a power rail may be formed on the backside of a semiconductor chip, integrated circuit device, or wafer (generally referred to herein as an integrated circuit device), rather than on the frontside thereof. As such, the power rail may be on a side of the integrated circuit device (e.g., a side of a substrate of the integrated circuit device) that is opposite from the active components (e.g., transistors) of the integrated circuit device. Moreover, conductive structures for data signals may be on the frontside of the integrated circuit device, and thus the BSPDN structure and the conductive structures for the data signals may be on opposite sides of the integrated circuit device. BSPDN structures may improve power rail effectiveness, voltage drop (i.e., IR drop), high power delivery performance, and further scaling of standard cell height.

### SUMMARY

Example embodiments of the present application result, in part, from the realization that overlay inaccuracies may occur during a self-aligned direct backside contact (SADBC) process. Pursuant to example embodiments herein, integrated circuit devices are provided that include spacers formed on lower surfaces of gate structures. The spacers may help facilitate the formation of backside contact structures (which may also be referred to as direct backside contacts (DBCs)) that have reliable electrical contact with the corresponding source/drain regions, while also helping to reduce the risk of electrical shorts between the backside contact structures and the gate structures.

An integrated circuit device, according to some embodiments herein, may include a substrate, a source/drain region on the substrate, a gate structure on the substrate and adjacent to the source/drain region, a backside contact structure extending in the substrate and electrically connected to the source/drain region, and a spacer in the substrate and on a lower surface of the gate structure, the spacer adjacent to the backside contact structure.

A method of forming an integrated circuit device, according to some embodiments herein, may include forming a transistor structure, the transistor structure comprising a source/drain region and a gate structure adjacent to the source/drain region, forming a spacer on the gate structure, forming a substrate on the spacer such that the spacer is in the substrate, and forming a backside contact structure in the substrate, the backside contact structure electrically connected to the source/drain region, overlapping the source/drain region in a direction perpendicular to an upper surface of the substrate, and adjacent to the spacer.

A method of forming an integrated circuit device, according to some embodiments herein, may include forming a placeholder in a first substrate, forming a transistor structure on the first substrate, the transistor structure comprising a source/drain region on the placeholder and a gate structure adjacent to the source/drain region, selectively removing the first substrate from around the placeholder, forming a spacer on the gate structure and adjacent to the placeholder, forming a second substrate on the spacer and the placeholder such that the spacer and the placeholder are in the second substrate, forming a first opening in the second substrate to expose the placeholder, forming a second opening in the second substrate by selectively removing the placeholder exposed by the first opening, and forming a backside contact structure in the first and second openings in the second substrate, the backside contact structure electrically connected to the source/drain region and overlapping the source/drain region in a direction perpendicular to an upper surface of the second substrate.

Other devices, apparatuses, and/or methods according to example embodiments will become more apparent to one of ordinary skill in the art upon review of the following drawings and detailed description. It is intended that all such additional embodiments, in addition to any and all combinations of the above embodiments, be included within this description, be within the scope of the present disclosure, and be protected by the accompanying claims.

### BRIEF DESCRIPTION OF THE DRAWINGS

FIG. 1A is a schematic plan or layout view illustrating an integrated circuit device according to some embodiments.

FIG. 1B is a schematic cross-sectional view taken along line A-A’ of FIG. 1A.

FIG. 2 is a flowchart illustrating a method of forming an integrated circuit device according to some embodiments.

FIGS. 3A, 3B, 3C, 3D, 3E, 3F, 3G, 3H, 3I, 3J and 3K, are schematic cross-sectional views illustrating a method of forming an integrated circuit device according to some embodiments.

### DETAILED DESCRIPTION

A backside power delivery network (BSPDN) structure may include a power delivery network that includes one or more power rails on (or in) a backside of an integrated circuit device. Different ways to connect from the frontside to the backside may include, for example, a front via backside power rail (FV-BPR) and a direct backside contact (DBC). The direct backside contact (which may also be referred to as a backside contact structure) may be more effective in terms of process capability and dimension limitations than other ways of connecting the frontside to the backside. As contacted poly pitch (CPP) becomes smaller, however, the direct backside contact may be more difficult to form due to patterning issues such as photo overlay and high aspect ratio etch process.

A self-aligned direct backside contact (SADBC) process may be used to form one or more direct backside contacts. The SADBC process may utilize placeholders that are formed beneath source/drain regions during the front-end-of-line (FEOL) portion of device fabrication. The placeholders may serve as etch guides to facilitate the formation of vertical openings from the backside of the device to the source/drain regions. For example, the placeholders may be exposed through a backside etching process and, after being exposed, the placeholders may be selectively removed to form openings that are self-aligned with the source/drain regions. Direct backside contacts may be formed in the openings and electrically connected to the corresponding source/drain regions to support backside power delivery from the BSPDN structure. The SADBC process may allow for self-alignment of the direct backside contacts and may simplify a fabrication process associated therewith by utilizing the placeholders formed during the FEOL portion of device fabrication.

Despite its advantages, the SADBC process may also present challenges. For example, overlay inaccuracies may occur during the backside etching process used to expose the placeholders, which may result in the formation of openings that are misaligned with the placeholders, leading to no exposure of the placeholders or only partial exposure of the placeholders. Due to this, the subsequent removal process of the placeholders may not remove the placeholders or may only partially remove the placeholders, leaving at least residual portions of the placeholders in the respective openings where the direct backside contacts are to be formed. As a result, the direct backside contacts may not be in electrical contact with the corresponding source/drain regions and instead may be in contact with the remaining placeholder material in the openings, thereby negatively impacting the performance and reliability of the integrated circuit device. Attempts to address this issue through over-etching (i.e., etching for longer and/or deeper than is typical) during the backside etching process may increase the risk of exposing gate structures adjacent to the source/drain regions, potentially resulting in an electrical short between the direct backside contacts and the gate structures.

Pursuant to example embodiments herein, integrated circuit devices are provided that include spacers formed on lower surfaces of gate structures. For example, the spacers may serve as etch stop layers during an SADBC process to form one or more direct backside contacts. During the SADBC process, placeholders on lower surfaces of source/drain regions may be exposed through a backside etching process. The spacers may allow for over-etching of the placeholders, while protecting adjacent gate structures from being exposed by the over-etching, to thereby reduce or prevent the risk of electrical shorts between the direct backside contacts and the gate structures. The over-etching of the placeholders may help ensure that the placeholders are fully exposed, even when overlay inaccuracies occur between the backside etch patterns and the placeholders. As such, a subsequent removal process of the placeholders may fully remove the placeholders, leaving the resulting openings substantially free of any residual material of the placeholders. Accordingly, direct backside contacts formed in the openings may make reliable electrical contact with the corresponding source/drain regions, thereby improving the performance and reliability of the integrated circuit device. The SADBC process according to example embodiments herein can be considered a double self-aligned process for the formation of direct backside contacts, since both the spacers formed on lower surfaces of gate structures and the selective removal of placeholders may allow for openings to be formed that are self-aligned with the source/drain regions.

Some examples of embodiments of the present disclosure are described in greater detail hereinafter with reference to the attached figures.

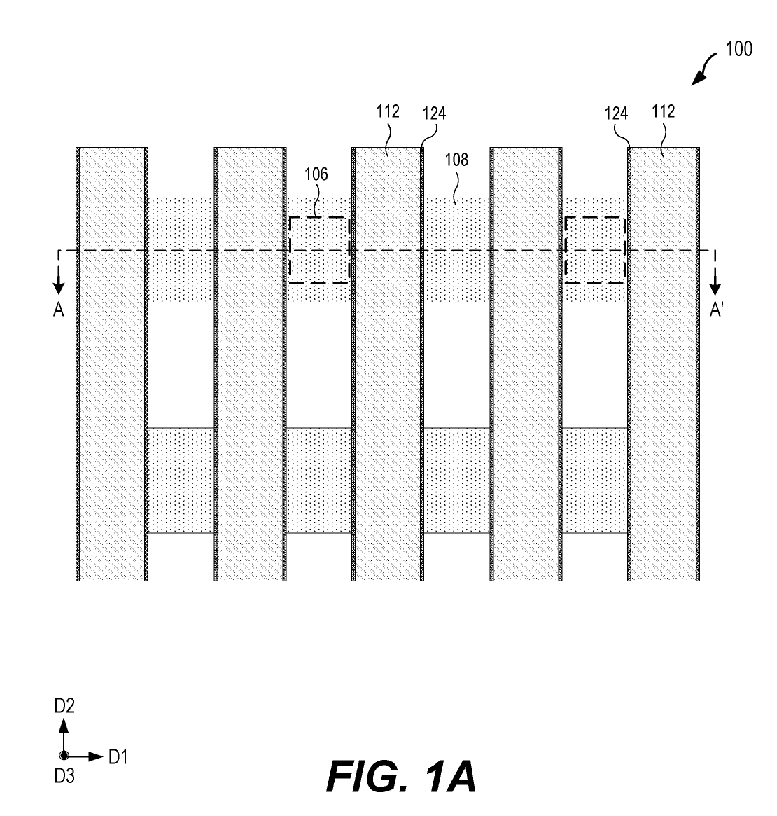

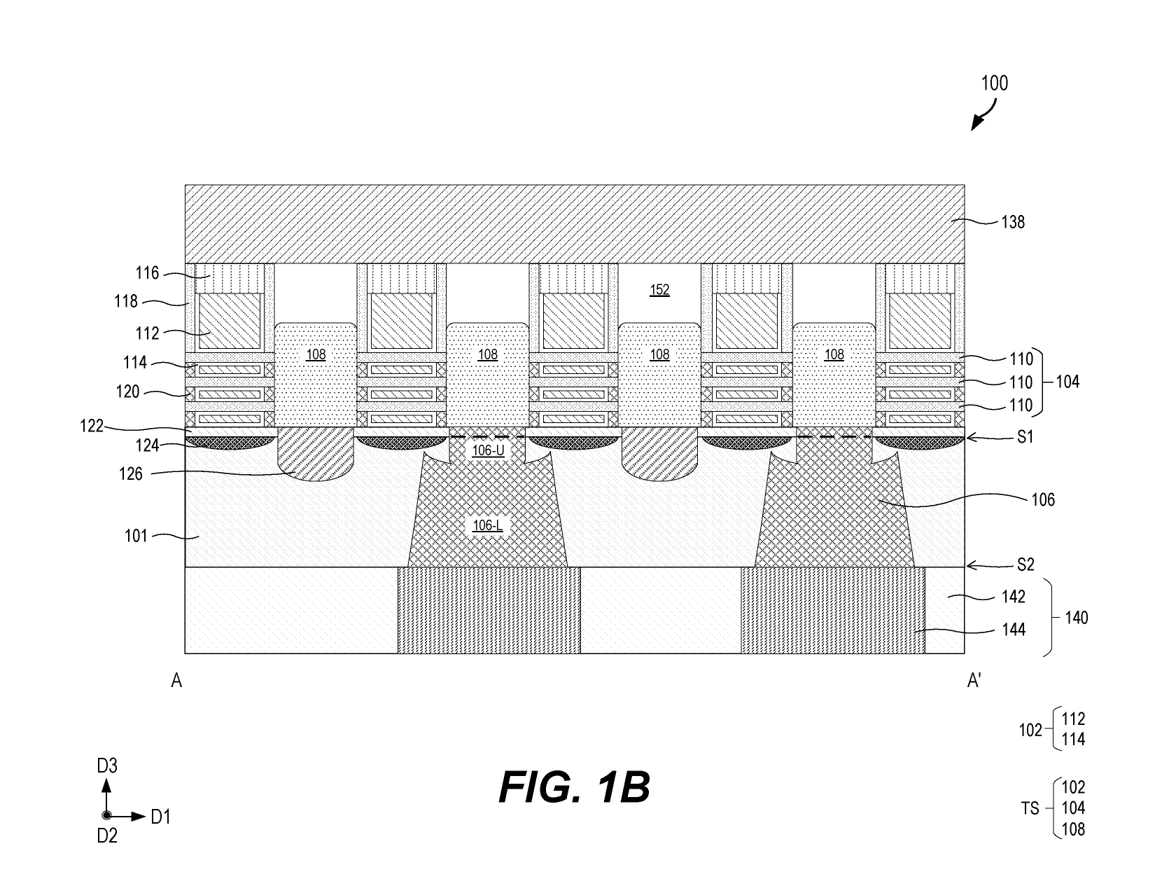

FIG. 1A is a schematic plan or layout view illustrating an integrated circuit device according to some embodiments. FIG. 1B is a schematic cross-sectional view taken along line A-A’ of FIG. 1A. Some of the layers/structures shown in FIG. 1B are omitted in FIG. 1A to help illustrate example embodiments of the present disclosure.

Referring to FIGS. 1A and 1B, an integrated circuit device 100 may include a substrate 101 (which may also be referred to as a backside insulating layer) and transistor structures TS (which may also be referred to as transistors) on an upper surface (or frontside) S1 of the substrate 101. The substrate 101 may extend in a first direction D1 (which may also be referred to as a first horizontal direction or X direction) and a second direction D2 (which may also be referred to as a second horizontal direction or Y direction). The first direction D1 and the second direction D2 may be parallel to a surface (e.g., the upper surface S1) of the substrate 101. For example, the first direction D1 may intersect the second direction D2. In some embodiments, the first direction D1 may be perpendicular to the second direction D2.

In some embodiments, the substrate 101 may include or may be formed of insulating material(s), for example, silicon oxide, silicon oxynitride, silicon nitride, silicon carbonitride, silicon boron nitride and/or a low-k dielectric material. The low-k dielectric material may include, for example, fluorine-doped silicon oxide, organosilicate glass, carbon-doped oxide, porous silicon dioxide, porous organosilicate glass, spin-on organic polymeric dielectrics and/or spin-on silicon based polymeric dielectrics. A thickness of the substrate 101 in a third direction D3 (which may also be referred to as a vertical direction or Z direction) may be, for example, in a range of about 50 nanometers (nm) to about 100nm, but is not limited thereto. In some embodiments, the third direction D3 may be perpendicular to the first direction D1 and/or the second direction D2. The third direction D3 may be perpendicular to a surface (e.g., the upper surface S1) of the substrate 101.

A first interlayer 122 may be provided on the upper surface S1 of the substrate 101. In some embodiments, the first interlayer 122 may extend between the substrate 101 and the transistor structures TS and may contact the upper surface S1 of the substrate 101 and the transistor structures TS. For example, the first interlayer 122 may include insulating material(s) (e.g., silicon oxide, silicon oxynitride, silicon nitride, silicon carbonitride and/or a low-k material). In some other embodiments, the first interlayer 122 may be omitted.

Each of the transistor structures TS may include a gate structure 102, a pair of source/drain regions 108, and a channel structure 104 that extends between the pair of source/drain regions 108 (e.g., in the first direction D1). The gate structure 102 may be on the channel structure 104 and may overlap the channel structure 104 in the third direction D3. As used herein, “an element A overlaps an element B in a direction X” (or similar language) means that there is at least one straight line that extends in the direction X and intersects both the elements A and B. For example, the gate structure 102 may at least partially surround the channel structure 104. In some embodiments, the channel structure 104 may extend in the first direction D1, and the gate structure 102 may extend in the second direction D2. It will be understood that “an element A surrounds an element B” (or similar language) as used herein means that the element A is at least partially around the element B but does not necessarily mean that the element A completely encloses the element B.

In some embodiments, each of the channel structures 104 may include a plurality of channel regions 110 stacked in the third direction D3, and the channel regions 110 may be spaced apart from each other in the third direction D3. For example, in some embodiments, the transistor structures TS may be nanosheet transistors that include a stack of nanosheet layers in each channel structure 104. Although FIG. 1B illustrates that each channel structure 104 includes three channel regions 110, embodiments of the present disclosure are not limited thereto. In some other embodiments, each channel structure 104 may include less than three channel regions 110 or more than three channel regions 110.

The channel structure 104 may include semiconductor material(s) (e.g., Si, Ge, SiGe, GaP, GaAs, SiC, SiGeC and/or InP). That is, each of the channel regions 110 may include semiconductor material(s) (e.g., Si, Ge, SiGe, GaP, GaAs, SiC, SiGeC and/or InP). In some embodiments, the channel regions 110 may be nanosheets that may have a thickness, for example, in a range of about 1nm to about 100nm in the third direction D3 or may be nanowires that may have a circular or elliptical cross-section with a diameter, for example, in a range of about 1nm to about 100nm. When the channel structure 104 includes a nanosheet or nanowire, the gate structure 102 may extend around (i.e., may at least partially surround) the channel structure 104 on multiple sides thereof.

The integrated circuit device 100 may include multiple gate structures 102 that extend (i.e., longitudinally extend) in the second direction D2 and are spaced apart from each other in the first direction D1. Each gate structure 102 may include a gate electrode 112 and a gate insulator 114.

The gate electrode 112 may include a single layer or multiple layers. In some embodiments, the gate electrode 112 may include a metal layer or a material that includes, for example, tungsten (W), aluminum (Al), copper (Cu), molybdenum (Mo), cobalt (Co) and/or ruthenium (Ru), and may additionally include work function layer(s) (e.g., a TiN layer, a TaN layer, a TiAl layer, a TiC layer, a TiAlC layer, a TiAlN layer and/or a WN layer). For example, the work function layer(s) of the gate electrode 112 may separate the metal layer(s) of the gate electrode 112 from the gate insulator 114. In some embodiments, gate electrodes 112 included in different gate structures 102 may include the same material(s).

The gate insulator 114 may extend between the gate electrode 112 and the channel structure 104. More particularly, the gate insulator 114 may contact and physically separate the gate electrode 112 and the channel structure 104 (including the channel regions 110). The gate insulator 114 may include a single layer or multiple layers (e.g., a silicon oxide layer and/or a high-k dielectric material layer). For example, the high-k dielectric material layer may include Al₂O₃, HfO₂, ZrO₂, HfZrO₄, TiO₂, Sc₂O₃, Y₂O₃, La₂O₃, Lu₂O₃, Nb₂O₅ and/or Ta₂O₅.

A gate capping layer 116 may be on an upper surface of the gate electrode 112. That is, the gate capping layer 116 may be on an uppermost portion of the gate electrode 112. The gate capping layer 116 may include, for example, silicon oxide, silicon oxynitride, silicon nitride, silicon carbonitride and/or a low-k material. In some embodiments, the gate capping layer 116 may include a different material from an upper gate insulating spacer 118 and/or a lower gate insulating spacer 120 (described in greater detail below), but the present disclosure is not limited thereto.

As mentioned above, each transistor structure TS may include a gate structure 102 and a channel structure 104 provided between a pair of source/drain regions 108 (e.g., in the first direction D1). That is, the pair of source/drain regions 108 may be spaced apart from each other in the first direction D1, with the gate structure 102 and the channel structure 104 therebetween. The pair of source/drain regions 108 may contact opposing side surfaces of the channel structure 104 that are spaced apart from each other in the first direction D1. That is, the pair of source/drain regions 108 may contact opposing side surfaces of the channel regions 110 included in the channel structure 104 (e.g., in the first direction D1). The pair of source/drain regions 108 may be electrically connected to the channel structure 104 (including the channel regions 110).

Each of the source/drain regions 108 may include a semiconductor layer (e.g., a silicon (Si) layer and/or a silicon germanium (SiGe) layer) and may additionally include dopants in the semiconductor layer. For example, each of the source/drain regions 108 may include an epitaxial semiconductor layer having dopants (i.e., impurities) therein.

In some embodiments, the transistor structures TS may be three-dimensional (3D) field-effect transistors (FETs) such as multi-bridge channel FETs (MBCFETs). In some other embodiments, the transistor structures TS may have structures different from that illustrated. For example, the transistor structures TS may be gate-all-around FETs (GAAFETs) including a single channel region, fin-shaped FETs (FinFETs), or stacked transistors (e.g., three-dimensional (3D) stacked FETs (3DSFETs)).

The integrated circuit device 100 may further include an upper gate insulating spacer 118 and a lower gate insulating spacer 120. The upper gate insulating spacer 118 may be between the gate electrode 112 and the source/drain region 108 (e.g., in the first direction D1). For example, the upper gate insulating spacer 118 may be between an upper portion of the gate electrode 112 and an upper portion of the source/drain region 108. The upper gate insulating spacer 118 may extend on side surfaces of the gate electrode 112, the gate insulator 114, the gate capping layer 116, and the source/drain region 108.

The lower gate insulating spacer 120 may be between the gate electrode 112 and the source/drain region 108 (e.g., in the first direction D1). For example, the lower gate insulating spacer 120 may be between a lower portion of the gate electrode 112 and a lower portion of the source/drain region 108. The lower gate insulating spacer 120 may extend on side surfaces of the gate electrode 112, the gate insulator 114, and the source/drain region 108. Portions of the lower gate insulating spacer 120 may be between adjacent ones of the channel regions 110 (e.g., in the third direction D3) and may also be between a lowermost one of the channel regions 110 and the substrate 101 (e.g., in the third direction D3).

In some embodiments, the upper gate insulating spacer 118 and the lower gate insulating spacer 120 may include the same material, but the present disclosure is not limited thereto. Each of the upper gate insulating spacer 118 and the lower gate insulating spacer 120 may include, for example, silicon oxide, silicon oxynitride, silicon nitride, silicon carbonitride and/or a low-k material. In some other embodiments, the upper gate insulating spacer 118 and/or the lower gate insulating spacer 120 may be omitted.

The integrated circuit device 100 may further include a second interlayer 152 on upper surfaces of the source/drain regions 108. For example, the second interlayer 152 may at least partially surround the source/drain regions 108. Although FIG. 1B illustrates the second interlayer 152 as a single layer, in some embodiments, the second interlayer 152 may include multiple layers. The second interlayer 152 may include, for example, silicon oxide, silicon oxynitride, silicon nitride, silicon carbonitride and/or a low-k material.

The integrated circuit device 100 may further include an upper structure 138 (which may also be referred to as a BEOL structure) on the gate structures 102, the source/drain regions 108, and the second interlayer 152. The upper structure 138 may include elements formed during the middle-of-line (MOL) portion and/or the back-end-of-line (BEOL) portion of device fabrication. The upper structure 138 may include conductive elements (e.g., wire(s) and/or via plug(s)) and insulating elements (e.g., interlayer(s) and/or spacer(s)). For example, the upper structure 138 may include an interlayer insulating layer, conductive wires (e.g., metal wires) that are provided in the interlayer insulating layer and are stacked in the third direction D3, and conductive via plugs (e.g., metal via plugs), each of which may electrically connect two conductive wires that are spaced apart from each other in the third direction D3. The conductive elements of the upper structure 138 may be electrically connected to, for example, the source/drain regions 108 and/or the gate structures 102.

The gate structures 102, the channel structures 104, and the source/drain regions 108 may be provided on the upper surface S1 of the substrate 101. The integrated circuit device 100 may further include backside contact structures 106 (shown by dashed boxes in FIG. 1A) that are electrically connected to respective ones of the source/drain regions 108. The backside contact structures 106 (which may also be referred to as direct backside contacts or backside source/drain contacts) may extend in the substrate 101 in the third direction D3. For example, the backside contact structures 106 may extend through the substrate 101 from a lower surface (or backside) S2 of the substrate 101 to be electrically connected to respective ones of the source/drain regions 108 on the upper surface (or frontside) S1 of the substrate 101. In some embodiments, the backside contact structures 106 may be in electrical contact with the source/drain regions 108. That is, the backside contact structures 106 may be in direct contact with the source/drain regions 108 and electrically connected thereto. For example, the backside contact structures 106 may be directly on lower surfaces of the source/drain regions 108. In some embodiments, an upper portion 106-U of each backside contact structure 106 may include a conductive layer (shown by a dashed line in FIG. 1B) that comprises a metal silicide layer (e.g., tungsten silicide, aluminum silicide, and/or copper silicide), a metal nitride layer (e.g., titanium nitride, tantalum nitride, and/or tungsten nitride), or a combination thereof. For example, the conductive layer included in the upper portion 106-U of the backside contact structure 106 may be provided in the first interlayer 122. In some other embodiments, the conductive layer may be omitted. In some embodiments, the upper portions 106-U of the backside contact structures 106 may not overlap the gate structures 102 and the channel structures 104 in the third direction D3. The backside contact structures 106 (e.g., the upper portions 106-U of the backside contact structures 106) may be formed in a double self-aligned manner based on spacers 124 (which may also be referred to as backside contact structure spacers) and placeholders 126 (which may also be referred to as source/drain placeholder elements), as described in greater detail below.

The backside contact structures 106 may be on and may respectively contact lower portions (e.g., bottom portions) or lower surfaces (e.g., bottom surfaces) of the source/drain regions 108. Some of the source/drain regions 108 may overlap the backside contact structures 106 in the third direction D3. Others of the source/drain regions 108 may not overlap the backside contact structures 106 in the third direction D3. For example, the others of the source/drain regions 108 may overlap placeholders 126 in the third direction D3. The backside contact structures 106 and/or backside gate contact structures (not shown) may include a metal layer or material including, for example, tungsten (W), aluminum (Al), copper (Cu), molybdenum (Mo), cobalt (Co) and/or ruthenium (Ru).

Still referring to FIGS. 1A and 1B, each backside contact structure 106 may include a lower portion 106-L and an upper portion 106-U on the lower portion 106-L. In some embodiments, the upper portion 106-U may not overlap the gate structure 102 and the channel structure 104 in the third direction D3, and the lower portion 106-L may overlap the gate structure 102 and the channel structure 104 in the third direction D3. For example, a width in the first direction D1 (e.g., a maximum width in the first direction D1) of the lower portion 106-L of the backside contact structure 106 may be greater than (i.e., wider than) a width in the first direction D1 (e.g., a maximum width in the first direction D1) of the upper portion 106-U of the backside contact structure 106. The upper portion 106-U may contact (e.g., may be directly on) the source/drain region 108 and may extend between the lower portion 106-L and the source/drain region 108. The upper portion 106-U and the lower portion 106-L may be a monolithic or unitary structure that is formed from a same material (i.e., without structurally or visibly separate interfaces therebetween) in some embodiments. Respective side surfaces of the upper and lower portions 106-U, 106-L may be formed at different angles and may thus have different slopes. Further, the respective side surfaces of the upper and lower portions 106-U, 106-L may not be aligned, resulting in at least one step difference between the respective side surfaces of the upper and lower portions 106-U, 106-L. As used herein, “a maximum width of an element A in a direction X” (or similar language) refers to the widest portion of the element A in the direction X.

In some embodiments, each backside contact structure 106 may overlap a pair of adjacent spacers 124 (described in greater detail below) in the third direction D3. For example, the lower portion 106-L of the backside contact structure 106 may overlap the spacers 124 in the third direction D3. In some embodiments, the backside contact structure 106 may be spaced apart from the spacers 124. For example, the lower portion 106-L of the backside contact structure 106 may be spaced apart from lower surfaces of the spacers 124 (e.g., in the third direction D3), with a portion of the substrate 101 therebetween. In some other embodiments, the backside contact structure 106 may be in contact with (e.g., may be directly on) the spacers 124. The spacer 124 may be between the backside contact structure 106 (e.g., the lower portion 106-L of the backside contact structure 106) and the gate structure 102 in the third direction D3. For example, the spacers 124 may separate (e.g., may electrically isolate) the backside contact structures 106 from the gate structures 102 to help prevent an electrical short (i.e., an unintended electrical connection) therebetween.

In some embodiments, a thickness (e.g., in the third direction D3) of the lower portion 106-L of the backside contact structure 106 may be greater than (i.e., thicker than) a thickness (e.g., in the third direction D3) of the upper portion 106-U of the backside contact structure 106. In some embodiments, the thickness (e.g., in the third direction D3) of the upper portion 106-U of the backside contact structure 106 may be less than a thickness (e.g., in the third direction D3) of the placeholder 126. That is, the placeholders 126 (described in greater detail below) may extend deeper into the substrate 101 (e.g., in the third direction D3) than the upper portions 106-U of the backside contact structures 106.

The integrated circuit device 100 may further include a backside power delivery network (BSPDN) structure 140 on the lower surface (or backside) S2 of the substrate 101. The backside contact structures 106 may electrically connect the BSPDN structure 140 to the respective source/drain regions 108. That is, the backside contact structures 106 may extend between (e.g., in the third direction D3) and may be electrically connected to the BSPDN structure 140 and respective ones of the source/drain regions 108. The BSPDN structure 140 may be provided on lower surfaces of the backside contact structures 106 and the lower surface S2 of the substrate 101. The BSPDN structure 140 may include a backside insulator 142 and one or more backside power rails 144 provided in the backside insulator 142. The backside power rail 144 may be electrically connected to the backside contact structure 106. The backside power rail 144 may include a metal layer or material including, for example, tungsten (W), aluminum (Al), copper (Cu), molybdenum (Mo), cobalt (Co) and/or ruthenium (Ru), and the backside insulator 142 may include, for example, silicon oxide, silicon oxynitride, silicon nitride, silicon carbonitride and/or a low-k material, although embodiments are not limited thereto.

The backside power rail 144 may be electrically connected to a power source with a predetermined voltage (e.g., a drain voltage (VDD) or a source voltage (VSS)). For example, the BSPDN structure 140 may include a power delivery network. The power delivery network may include a wiring network, which is used to deliver power (e.g., gate voltages and/or source/drain voltages) to the backside power rail 144. The source/drain region 108 may be electrically connected to the power source through the backside contact structure 106 and the backside power rail 144. For example, each backside contact structure 106 may deliver a drain voltage (VDD) or a source voltage (VSS) from the BSPDN structure 140 to a respective source/drain region 108. The backside contact structure 106 may be between the backside power rail 144 and the source/drain region 108 (e.g., in the third direction D3). In some embodiments, one or more conductive plugs may be provided between the backside contact structure 106 and the backside power rail 144. The backside contact structure 106 and the conductive plug may include the same materials. For example, the backside contact structure 106 and the conductive plug may be integrated in a monolithic or unitary structure, that is, a structure formed by the same process or the same series of processes without a structurally or visibly separate interface therebetween.

As used herein, the backside power rail 144 may refer to one or more conductive elements included in the BSPDN structure 140. For example, the backside power rail 144 may include a power rail, a conductive via plug, and/or a conductive wire included in the BSPDN structure 140. That is, while illustrated as including the backside power rail 144 and the backside insulator 142, it will be understood that the BSPDN structure 140 may include one or more conductive layers (e.g., metal layers) stacked in the third direction D3 that provide backside power delivery to the transistor structures TS. The conductive layers may respectively be included in insulating layers, and conductive via plugs (e.g., metal via plugs) may electrically connect the conductive layers to each other in the third direction D3. For example, although the backside insulator 142 is illustrated as a single layer, in some embodiments, the backside insulator 142 may include multiple insulating layers stacked on the lower surface S2 of the substrate 101 (e.g., in the third direction D3). The conductive layers may include one or more conductive wires (e.g., metal wires). In some embodiments, an intervening structure (not shown) may be provided between the substrate 101 and the BSPDN structure 140 and may separate the substrate 101 from the BSPDN structure 140. The BSPDN structure 140 may increase a power delivery efficiency in the integrated circuit device 100, reduce an area used for power delivery in the integrated circuit device 100, and/or improve a voltage drop (i.e., IR drop) in the integrated circuit device 100.

Still referring to FIGS. 1A and 1B, the integrated circuit device 100 may further include placeholders 126 in the substrate 101 (e.g., in the upper portion of the substrate 101). In some embodiments, the placeholders 126 may include a material different from the substrate 101 and the backside contact structures 106. The placeholders 126 may include, for example, a semiconductor material (e.g., Si or SiGe) and/or an insulating material (e.g., silicon oxide, silicon oxynitride, silicon nitride, silicon carbonitride, silicon boron nitride and/or a low-k material).

A lower portion of the substrate 101 may be between the placeholders 126 and the BSPDN structure 140 (e.g., in the third direction D3). In some embodiments, lower portions (e.g., lower surfaces) of the placeholders 126 may be convex toward the lower surface (or backside) S2 of the substrate 101 (e.g., away from the source/drain regions 108). For example, the lower surfaces of the placeholders 126 may have a curved or rounded shape that is convex toward the lower surface S2 of the substrate 101.

The placeholders 126 may be on lower surfaces of respective ones of the source/drain regions 108. That is, some of the source/drain regions 108 may overlap the placeholders 126 in the third direction D3. Others of the source/drain regions 108 may not overlap the placeholders 126 in the third direction D3. For example, the others of the source/drain regions 108 may overlap the backside contact structures 106 in the third direction D3. In some embodiments, the placeholders 126 may be directly on the lower surfaces of the source/drain regions 108. That is, the placeholders 126 may be on and may respectively contact lower portions (e.g., bottom portions) or lower surfaces (e.g., bottom surfaces) of the source/drain regions 108. In some embodiments, a placeholder 126 may be on a lower surface of a first source/drain region 108 included in a transistor structure TS, and a backside contact structure 106 may be on a lower surface of a second source/drain region 108 included in the transistor structure TS. For example, the placeholder 126 may be adjacent to the backside contact structure 106 (e.g., in the first direction D1), with a spacer 124 therebetween. In some embodiments, the first source/drain region 108 on the placeholder 126 may be electrically connected to a frontside contact structure (not shown) and may not overlap the backside contact structure 106 in the third direction D3. For example, the frontside contact structure may be provided in the second interlayer 152 and may extend through the second interlayer 152 (e.g., in the third direction D3) to electrically connect the first source/drain region 108 to a conductive element (e.g., a conductive wire and/or a conductive via plug) of the upper structure 138 for power and/or data delivery thereto, although embodiments are not limited thereto.

In some embodiments, adjacent backside contact structures 106 may be spaced apart from each other (e.g., in the first direction D1), with the placeholder 126 therebetween. For example, a parasitic capacitance between adjacent backside contact structures 106 may be reduced or avoided by forming the backside contact structures 106 on lower surfaces of some of the source/drain regions 108, while forming the placeholders 126 on lower surfaces of others of the source/drain regions 108 and between adjacent ones of the backside contact structures 106 (e.g., in the first direction D1). In some embodiments, the placeholder 126 may overlap the upper portion 106-U and the lower portion 106-L of the backside contact structure 106 in the first direction D1. A thickness of the placeholder 126 (e.g., in the third direction D3) may be greater than a thickness of the spacer 124 (e.g., in the third direction D3). That is, the placeholders 126 may extend deeper into the substrate 101 (e.g., in the third direction D3) than the spacers 124. In some embodiments, each placeholder 126 may be between a pair of adjacent spacers 124 (e.g., in the first direction D1). For example, the placeholder 126 may overlap the spacers 124 in the first direction D1.

Still referring to FIGS. 1A and 1B, the integrated circuit device 100 may further include spacers 124 respectively on lower portions (e.g., bottom portions) or lower surfaces (e.g., bottom surfaces) of the gate structures 102. For example, the spacers 124 may be in the substrate 101 (e.g., in the upper portion of the substrate 101) and on lower surfaces of the gate structures 102. The spacer 124 may be adjacent to the backside contact structure 106 (e.g., in the first direction D1). For example, the spacer 124 may be adjacent to the upper portion 106-U of the backside contact structure 106. The gate structure 102 (including the gate electrode 112 and the gate insulator 114) and the channel structure 104 (including the channel regions 110) may overlap the spacer 124 in the third direction D3. The spacers 124 may include or may be formed of insulating material(s) selected, for example, to provide an etch selectivity with respect to the substrate 101 and the placeholders 126. In some embodiments, each spacer 124 may include a nitride material (e.g., silicon nitride, aluminum nitride, or a combination thereof). For example, the nitride material may serve as an etch stop material and may offer advantages in terms of etch selectivity, chemical stability, and dielectric performance compared to other insulating materials, while also minimizing process-induced variability that may shift threshold voltages within the integrated circuit device 100. In some other embodiments, the spacers 124 may include or may be formed of insulating material(s) other than a nitride material (e.g., silicon oxide).

The spacers 124 may be laterally spaced apart from each other (e.g., in the first direction D1). In some embodiments, the spacers 124 may not overlap (i.e., may be free of overlap with) the source/drain regions 108 in the third direction D3. At least some of the spacers 124 may overlap the backside contact structures 106 (e.g., the lower portions 106-L of the backside contact structures 106) in the third direction D3. In some embodiments, the spacers 124 may be spaced apart from the backside contact structures 106. For example, a portion of the substrate 101 may be between the spacer 124 and the backside contact structure 106 (e.g., in the first direction D1 and/or the third direction D3). In some other embodiments, the spacers 124 may be in contact with (e.g., may be directly on) the backside contact structures 106. In some embodiments, the spacer 124 may be between the backside contact structure 106 and the placeholder 126 (e.g., in the first direction D1).

A lower portion of the substrate 101 may be between the spacers 124 and the BSPDN structure 140 (e.g., in the third direction D3). In some embodiments, lower portions (e.g., lower surfaces) of the spacers 124 may be convex toward the lower surface (or backside) S2 of the substrate 101 (e.g., away from the gate structures 102). For example, the lower surfaces of the spacers 124 may have a curved or rounded shape that is convex toward the lower surface S2 of the substrate 101. In some embodiments, each spacer 124 may have a hemisphere shape (i.e., a half-sphere shape), with a lower surface that is curved or rounded toward the lower surface S2 of the substrate 101 and an upper surface that is substantially planar or flat, although the present disclosure is not limited thereto.

In some embodiments, the spacers 124 may extend for a portion of or substantially all of the length of the gate structures 102 in the second direction D2. For example, the spacers 124 may respectively be formed on the lower surfaces of the gate structures 102 and may extend for substantially all of the length of the gate structures 102 in the second direction D2, as shown in FIG. 1A. In some embodiments, a length of the spacer 124 in the second direction D2 may be substantially equal to a length of the gate structure 102 in the second direction D2. The gate structure 102 (e.g., the gate electrode 112) may overlap (e.g., may cover) most of the spacer 124 in a plan view, and thus only the outer portions of each spacer 124 in the first direction D1 are shown in FIG. 1A. The spacers 124 may extend in the second direction D2 and may be spaced apart from each other in the first direction D1. The length of the spacer 124 in the second direction D2 may be greater than (i.e., longer than) a length of the source/drain region 108 in the second direction D2. For example, a deposition process used to form the spacers 124 may be simplified and costs associated therewith may be reduced by respectively forming the spacers 124 on the lower surfaces of the gate structures 102 (e.g., the lower surfaces of the gate electrodes 112) along substantially all of their length in the second direction D2. In some other embodiments, a length of the spacer 124 in the second direction D2 may be less than a length of the gate structure 102 in the second direction D2.

In some embodiments, the first interlayer 122 may be between (e.g., in the third direction D3) the gate structure 102 and the spacer 124. For example, the spacer 124 may be formed on a lower surface of the first interlayer 122. In some embodiments, the spacer 124 may include a different material from the substrate 101, the first interlayer 122, and the placeholders 126. For example, the spacer 124 may include a nitride material and the first interlayer 122 and/or the substrate 101 may include an oxide material, although embodiments are not limited thereto. In some embodiments, the placeholders 126 may include a different material from the substrate 101 and the first interlayer 122. In some other embodiments, the first interlayer 122 may be omitted, and the spacer 124 may be formed directly on a lower surface of the gate structure 102 (e.g., directly on a lower surface of the gate insulator 114).

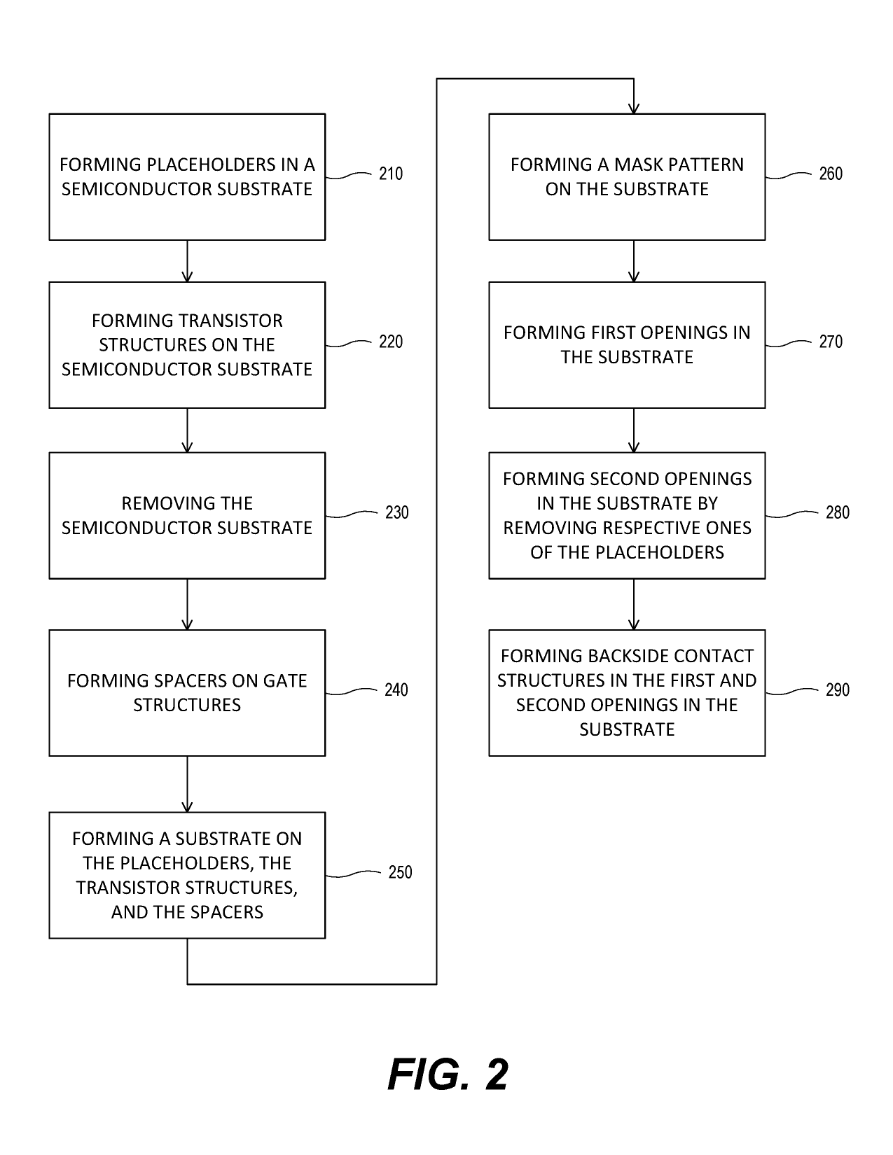

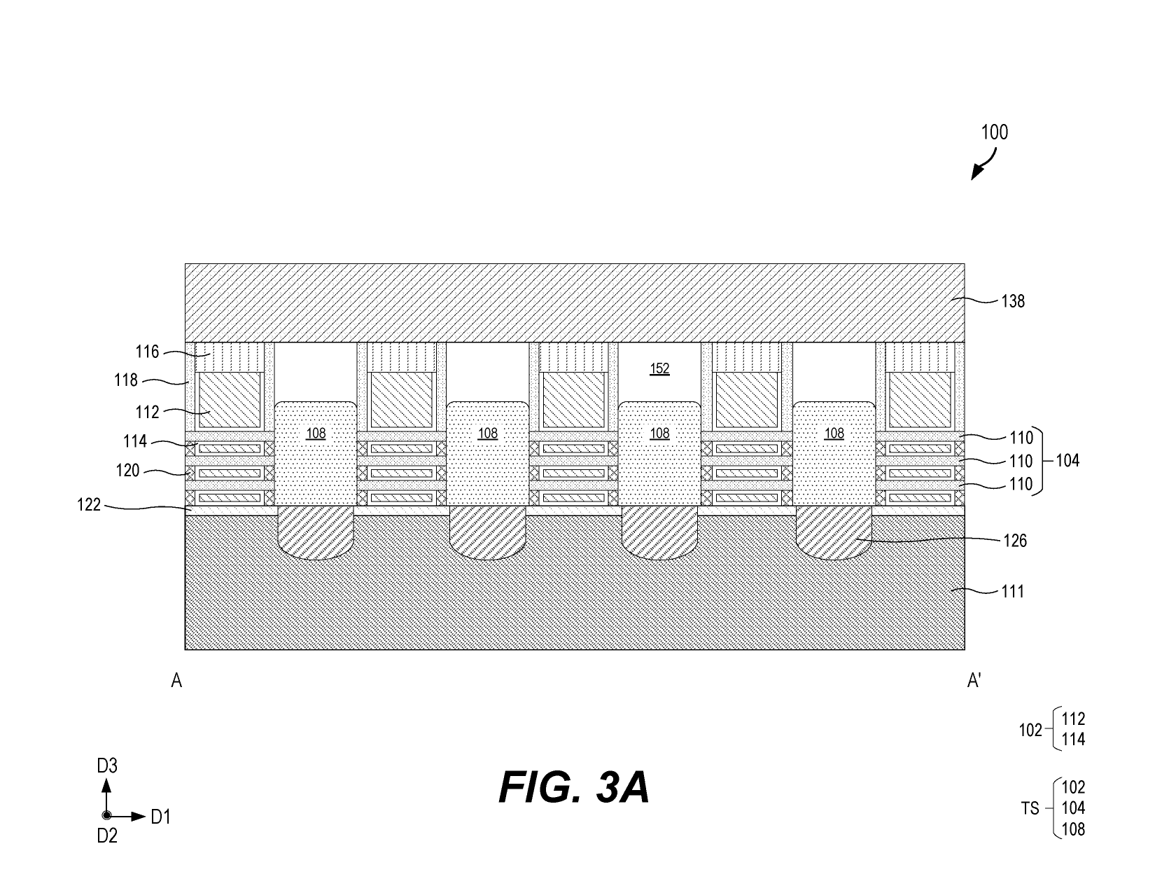

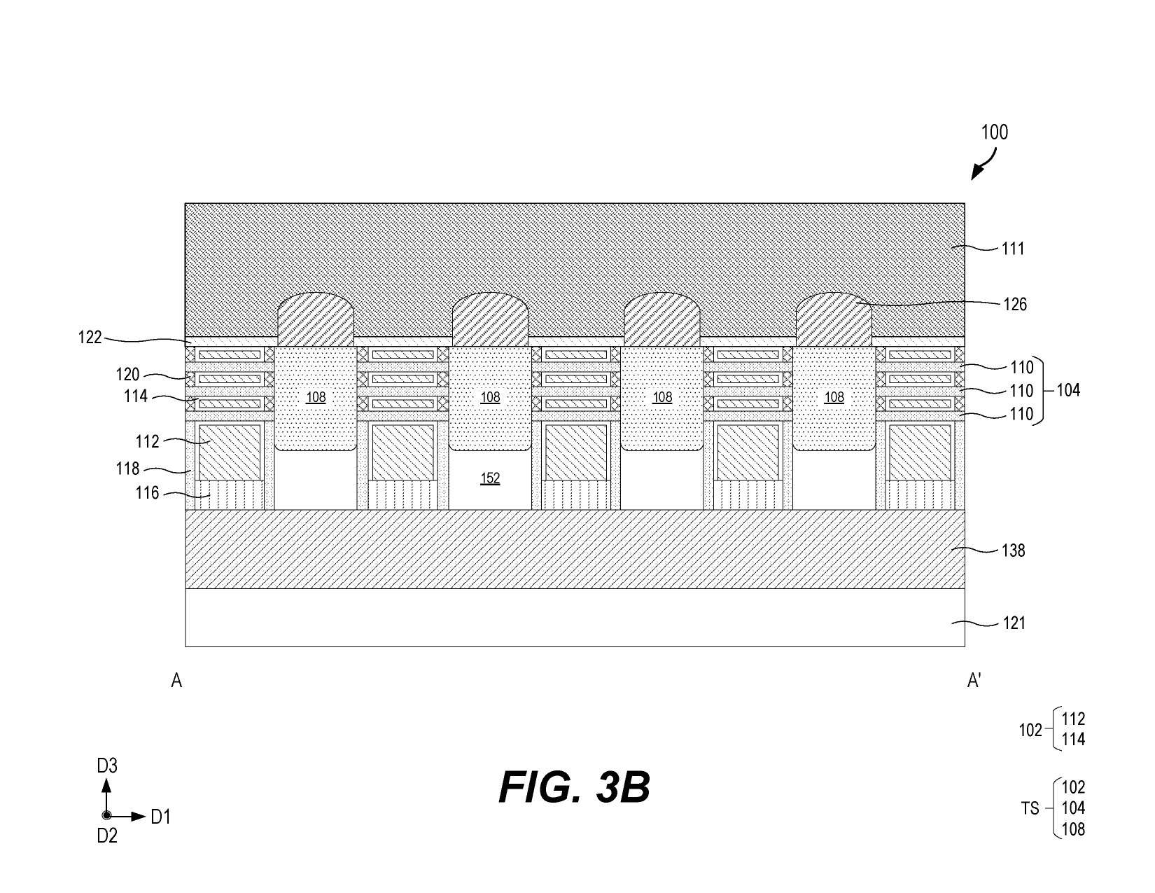

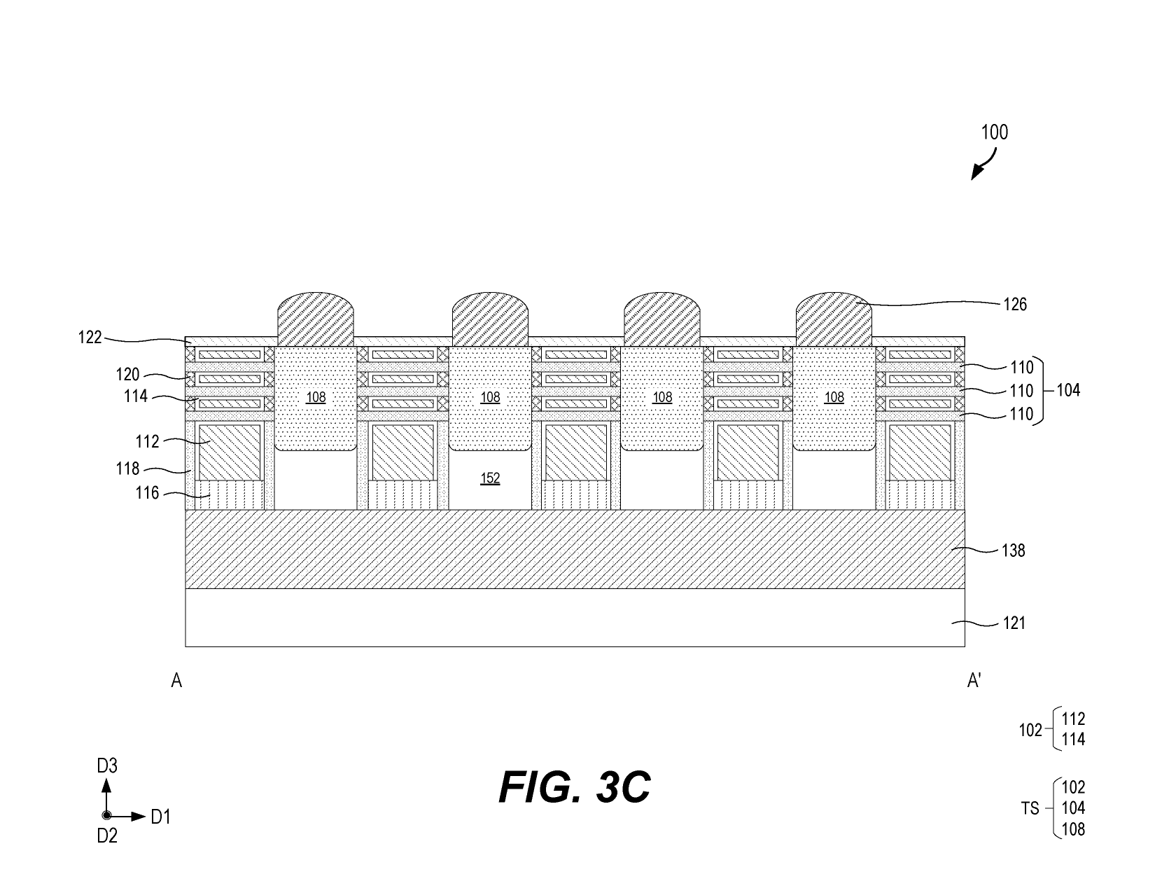

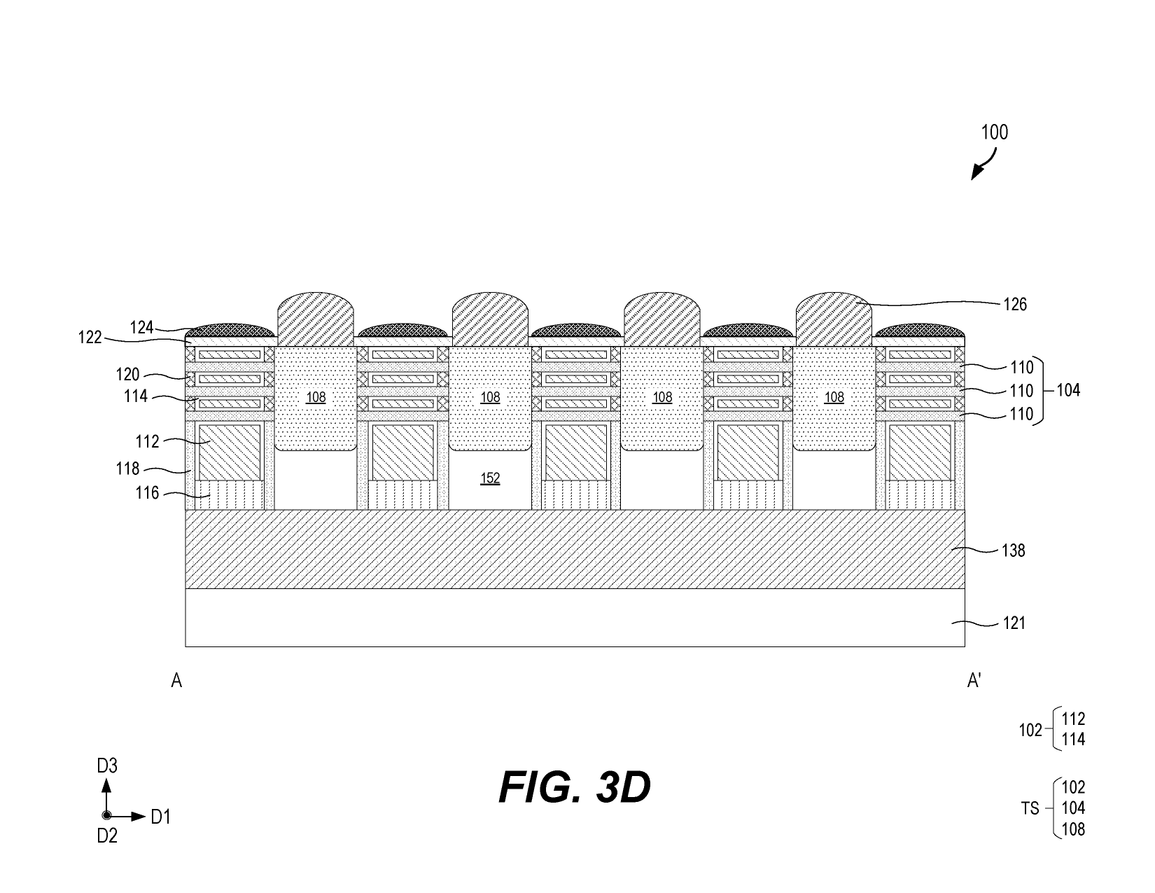

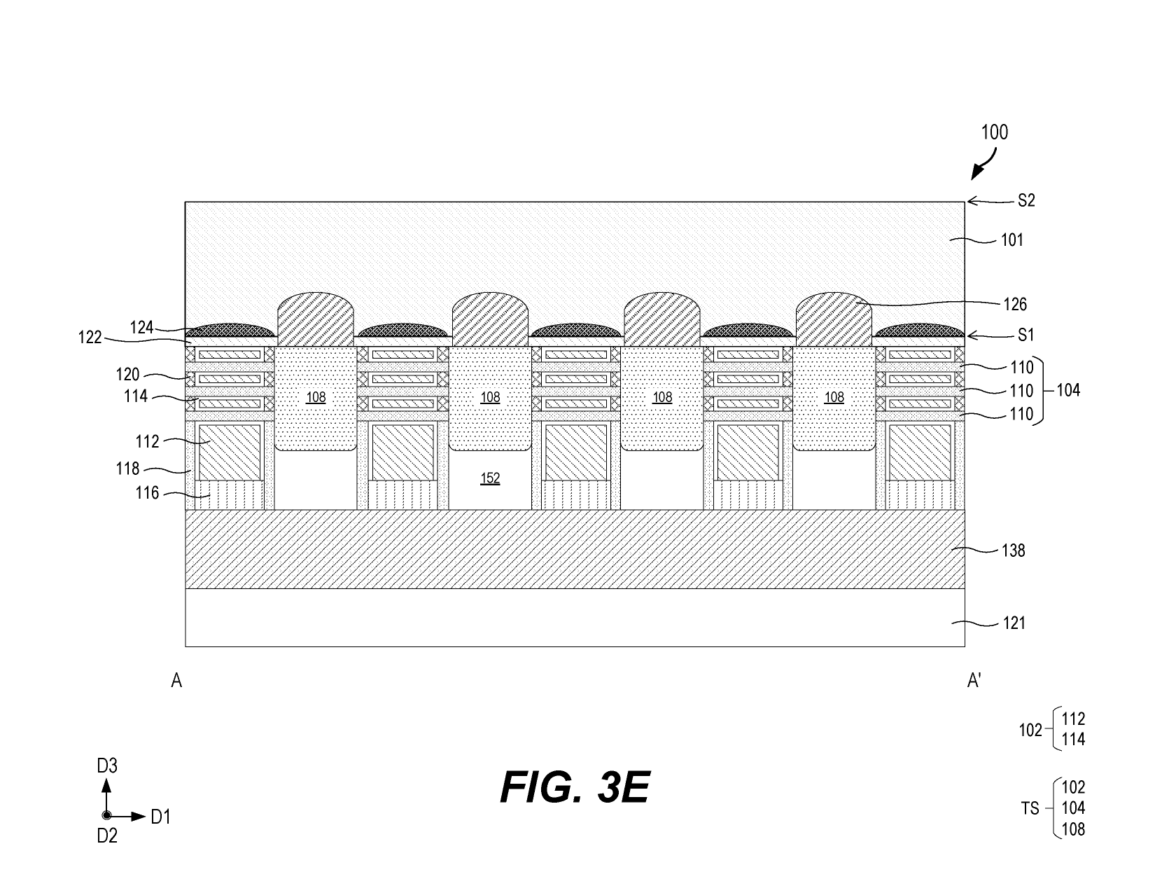

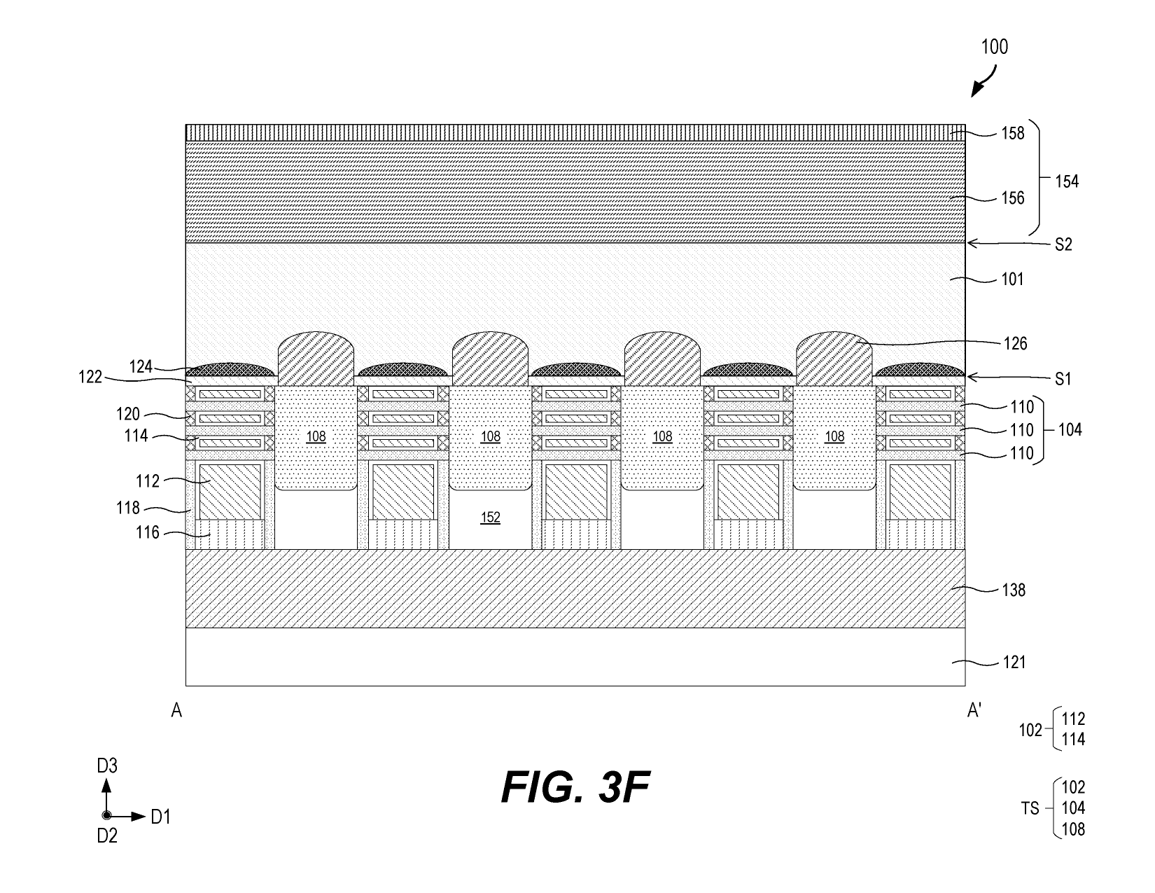

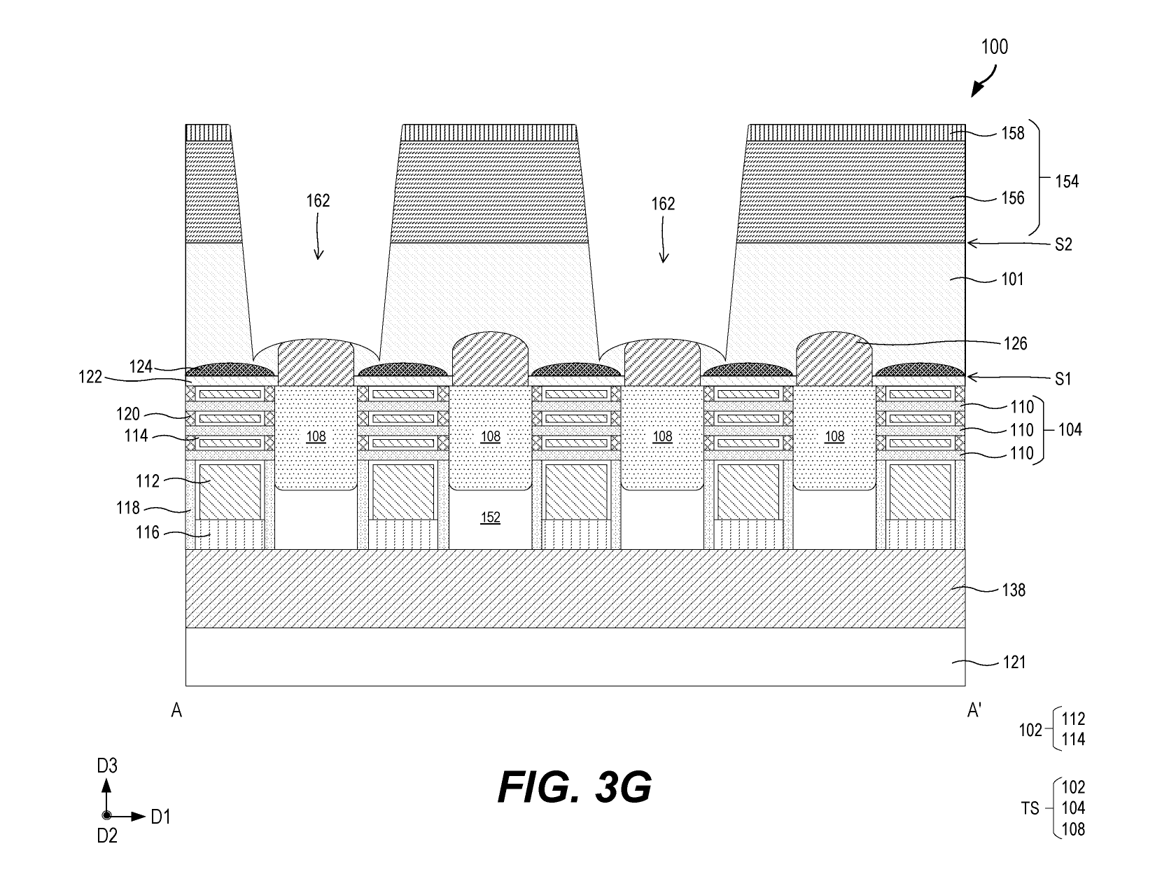

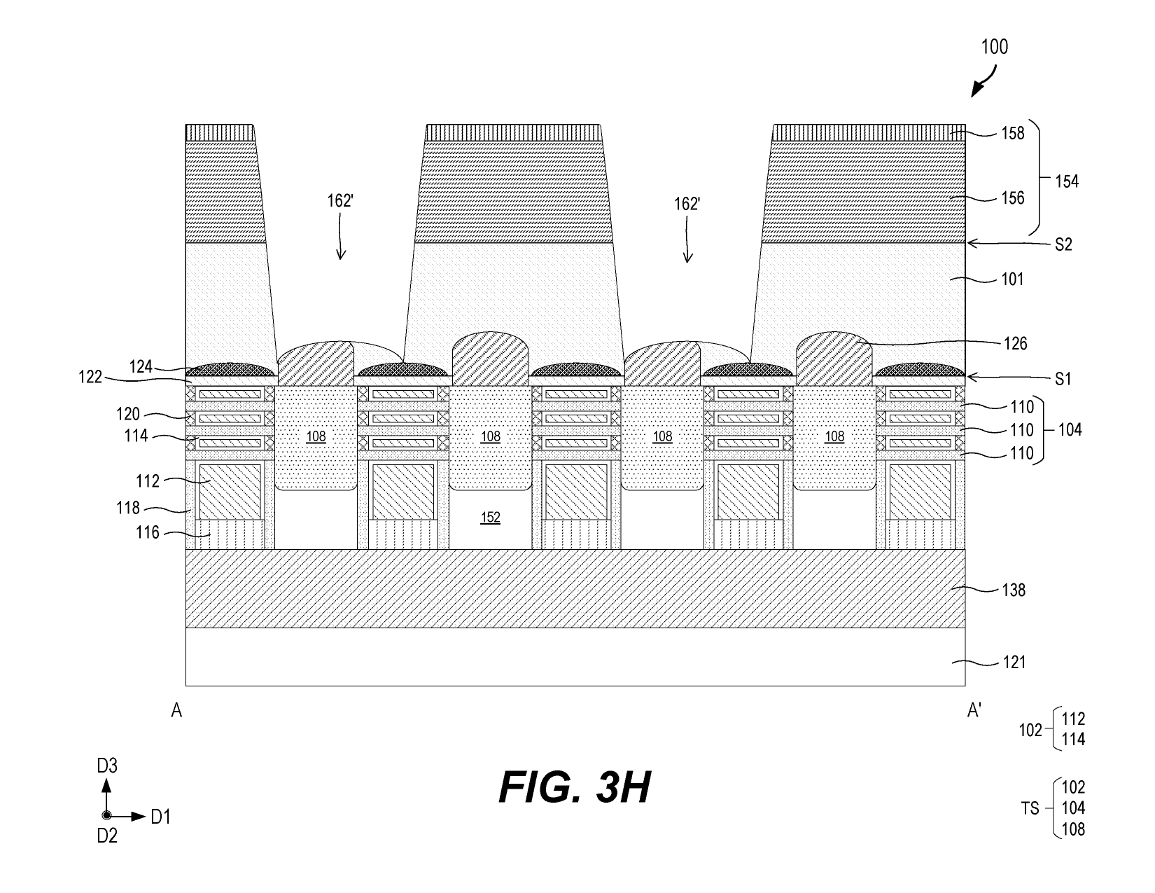

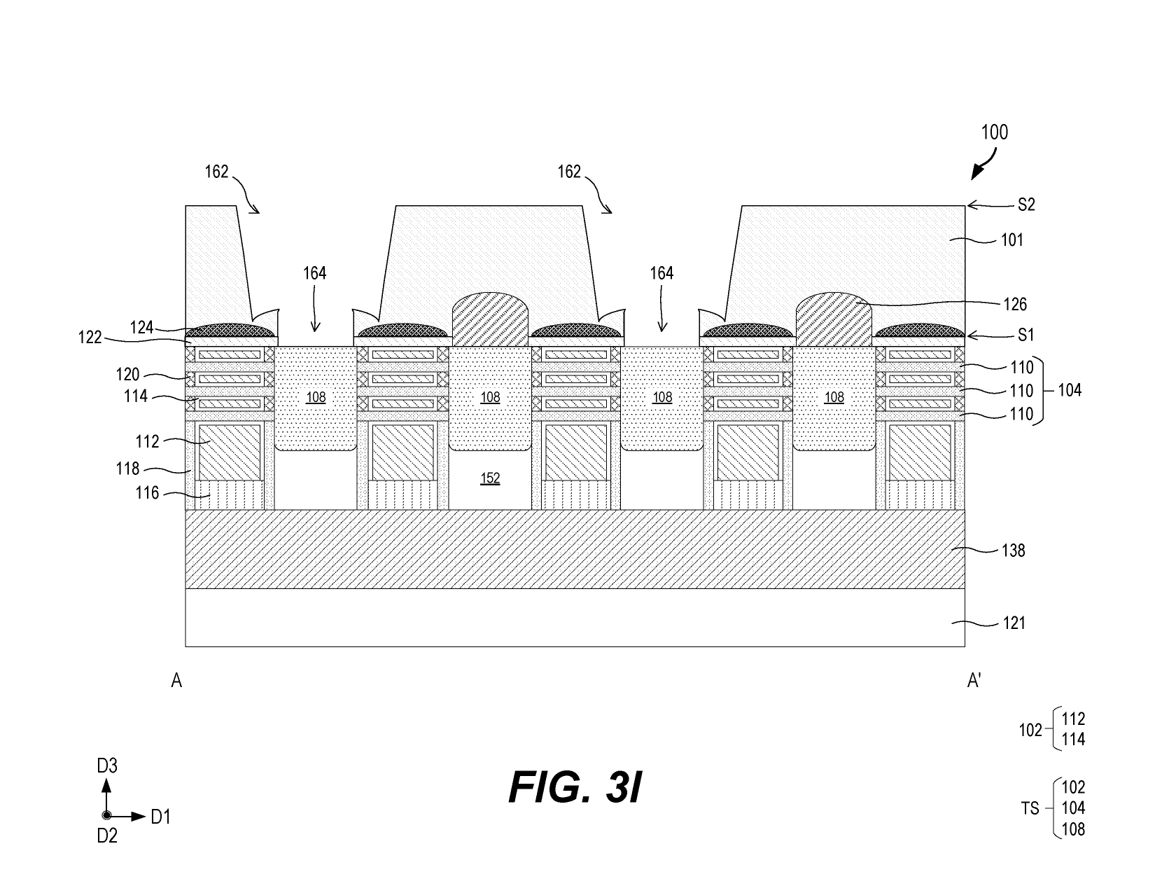

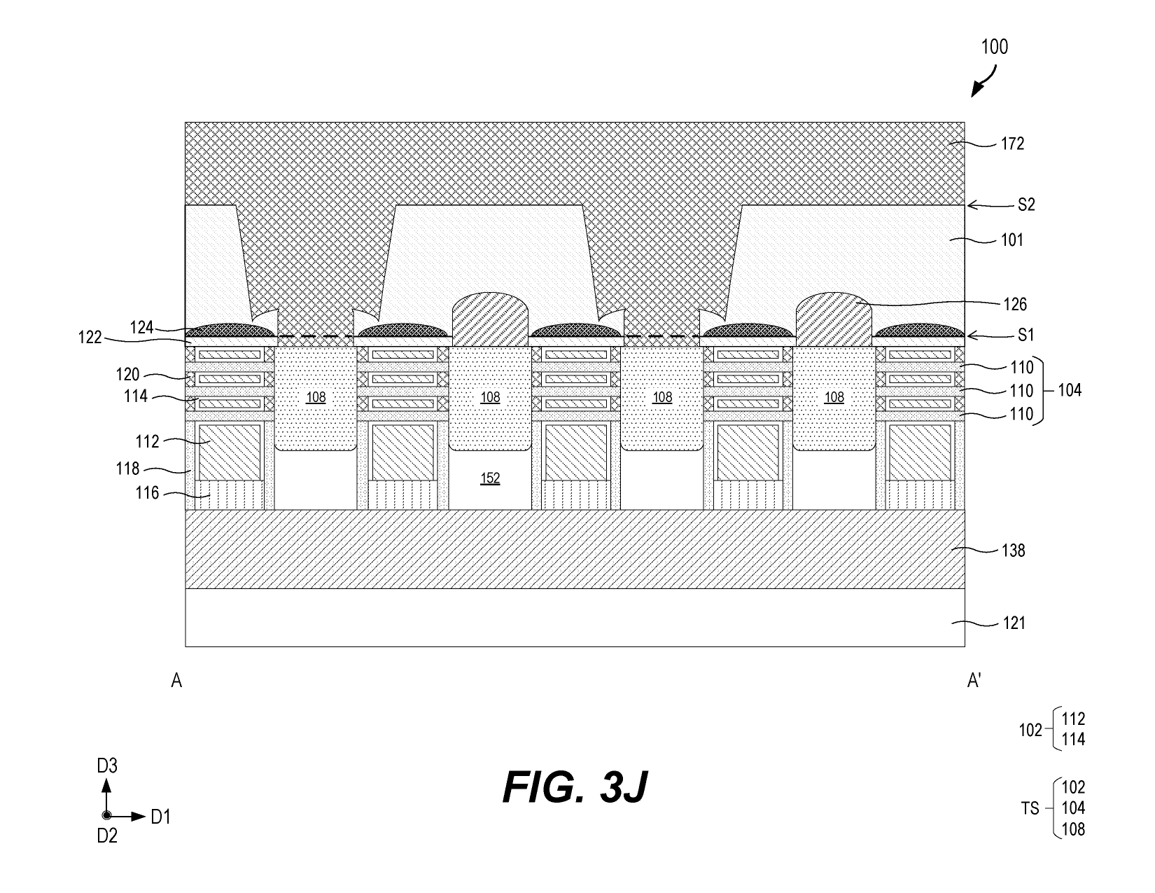

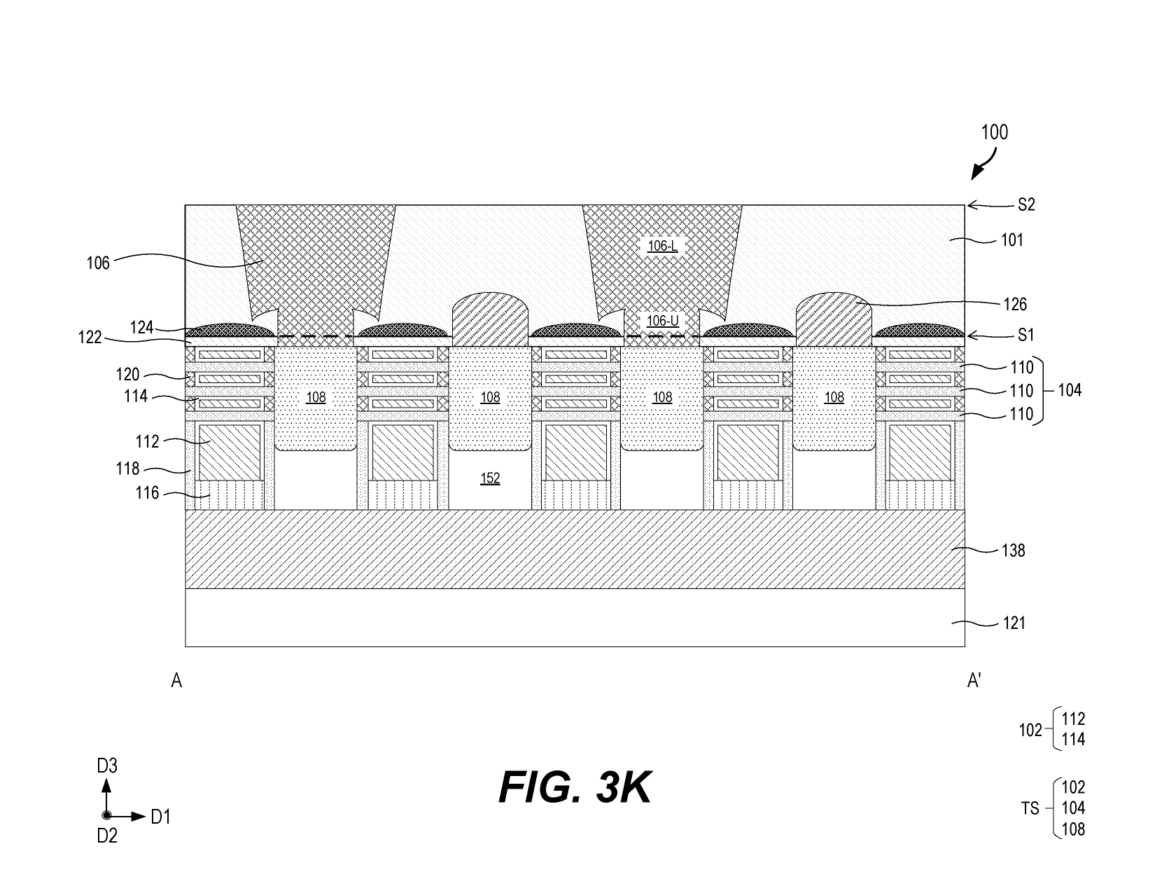

FIG. 2 is a flowchart illustrating a method of forming an integrated circuit device according to some embodiments. FIGS. 3A-K are schematic cross-sectional views illustrating a method of forming an integrated circuit device according to some embodiments. In particular, FIGS. 3A-K are cross-sectional views corresponding to the line A-A’ of FIG. 1A.

Referring to FIGS. 2 and 3A, placeholders 126 may be formed in a semiconductor substrate 111 (Block 210 in FIG. 2). Front-end-of line (FEOL) processes may be performed on the semiconductor substrate 111 to form the placeholders 126. In some embodiments, the placeholders 126 may be epitaxially grown. For example, the placeholders 126 may be formed by performing an epitaxial growth process using the semiconductor substrate 111 as a seed layer. In some other embodiments, the placeholders 126 may be formed by forming recesses (i.e., openings) in the semiconductor substrate 111 beneath areas where the source/drain regions 108 are to be formed and then performing a deposition process in the recesses. In some further embodiments, the placeholders 126 may be formed by implanting impurities into the semiconductor substrate 111 beneath areas where the source/drain regions 108 are to be formed. The placeholders 126 may include, for example, a semiconductor material and/or an insulating material. In some embodiments, the placeholders 126 may include a SiGe layer having a concentration of germanium in a range of about 15 at% to about 25 at%, but the present disclosure is not limited thereto.

Still referring to FIGS. 2 and 3A, transistor structures TS may be formed on the semiconductor substrate 111 (Block 220 in FIG. 2). FEOL processes may be performed (including fabrication of the gate structures 102, channel structures 104, source/drain regions 108, and metal interconnection layers or structures) on the semiconductor substrate 111 to form the transistor structures TS. FEOL processes may also be performed to form the gate capping layer 116, the upper gate insulating spacer 118, the lower gate insulating spacer 120, the first interlayer 122, and the second interlayer 152 on the semiconductor substrate 111. Further, the upper structure 138 may be formed on the gate structures 102, the source/drain regions 108, and the second interlayer 152. For example, middle-of-line (MOL) processes and/or back-end-of-line (BEOL) processes may be performed to form the upper structure 138.

The semiconductor substrate 111 (which may also be referred to as a backside semiconductor substrate or a first substrate) may include semiconductor material(s) (e.g., Si, Ge, SiGe, GaP, GaAs, SiC, SiGeC and/or InP). For example, the semiconductor substrate 111 may be provided as a bulk wafer, an epitaxial layer, a silicon-on-insulator (SOI) layer, a semiconductor-on-insulator (SeOI) layer, or the like. Although FIG. 3A illustrates the semiconductor substrate 111 as a single layer, in some embodiments, the semiconductor substrate 111 may include multiple layers (e.g., multiple semiconductor layers).

In some embodiments, the source/drain regions 108 may be epitaxially grown. For example, the source/drain regions 108 may be formed by performing an epitaxial growth process using the channel regions 110 as a seed layer, and the source/drain regions 108 may be epitaxially grown from opposing side surfaces of the channel regions 110 (e.g., in the first direction D1). The source/drain regions 108 may respectively be formed on the placeholders 126. For example, the source/drain regions 108 may overlap the placeholders 126 in the third direction D3. In some embodiments, the gate structures 102 (including the gate electrodes 112 and the gate insulators 114) may be formed using a replacement metal gate (RMG) process.

Referring to FIG. 3B, a carrier wafer 121 (which may also be referred to as a carrier substrate) may be formed on the upper surface of the upper structure 138. For example, the carrier wafer 121 may be bonded to the upper surface of the upper structure 138. Subsequently, the carrier wafer 121 may be turned over, so that the structure of the integrated circuit device 100 shown in FIG. 3A is turned over (i.e., inverted in the third direction D3). Hereinafter, references to lower surfaces, upper surfaces, lower portions, upper portions and the like of layers/structures shown in the cross-sectional views of FIGS. 3B-K will refer to these surfaces or portions as shown in the cross-sectional view of FIG. 1B. It will be understood that references to lower surfaces or lower portions may be shown as upper surfaces or upper portions (or vice versa) in the cross-sectional views of FIGS. 3B-K, since the structure of the integrated circuit device 100 shown in FIGS. 3B-K is turned over (i.e., inverted in the third direction D3) from that shown in FIG. 1B.

Referring to FIGS. 2 and 3C, the semiconductor substrate 111 may be removed (Block 230 in FIG. 2). For example, a removal process (e.g., a grinding process, a wet etching process, a dry etching process and/or a chemical mechanical polishing (CMP) process) may be performed to remove the semiconductor substrate 111. The placeholders 126 may be exposed after the semiconductor substrate 111 is removed. In some embodiments, the placeholders 126 may have an etch selectivity (i.e., may exhibit etch selectivity) with respect to the semiconductor substrate 111, allowing for the semiconductor substrate 111 to be removed without removing the placeholders 126. For example, the semiconductor substrate 111 may be selectively removed from around the placeholders 126.

Referring to FIGS. 2 and 3D, spacers 124 may be formed on the gate structures 102 (Block 240 in FIG. 2). For example, the spacers 124 may respectively be formed on lower surfaces of the gate structures 102. In some embodiments, a deposition process (e.g., a chemical vapor deposition (CVD) process and/or an atomic layer deposition (ALD) process) may be performed to form (i.e., deposit) the spacers 124 on the lower surfaces of the gate structures 102. For example, the spacers 124 may be selectively deposited on the gate structures 102 by the deposition process and may overlap the gate structures 102 and the channel structures 104 in the third direction D3. In some embodiments, the selective deposition of the spacers 124 may allow for the spacers 124 to be free of overlap with the source/drain regions 108 in the third direction D3, which may help ensure that backside contact structures 106 to be formed in subsequent operations (see FIGS. 3J-K) can make reliable electrical contact with the corresponding source/drain regions 108. The spacers 124 may be formed adjacent to the placeholders 126. The spacers 124 may have an etch selectivity with respect to the placeholders 126. For example, the spacers 124 may include a different material from the placeholders 126.

In some embodiments, each spacer 124 may include a nitride material (e.g., silicon nitride, aluminum nitride, or a combination thereof). For example, the nitride material may serve as an etch stop material and may offer advantages in terms of etch selectivity, chemical stability, and dielectric performance compared to other insulating materials, while also minimizing process-induced variability that may shift threshold voltages within the integrated circuit device 100. In some embodiments, the deposition process and/or the material(s) used to form the spacers 124 may cause lower portions (e.g., lower surfaces) of the spacers 124 to be convex away from the gate structures 102. For example, the lower surfaces of the spacers 124 may have a curved or rounded shape that is convex away from the gate structures 102. In some embodiments, each spacer 124 may have a hemisphere shape (i.e., a half-sphere shape), with a lower surface that is curved or rounded away from the gate structure 102 and an upper surface that is substantially planar or flat, although the present disclosure is not limited thereto.

In some embodiments, the spacers 124 may respectively be formed on the lower surfaces of the gate structures 102 and may extend for up to substantially all of the length of the gate structures 102 in the second direction D2 (see FIG. 1A). That is, the length of each spacer 124 in the second direction D2 may be substantially equal to the length of each gate structure 102 in the second direction D2. Further, the length of each spacer 124 in the second direction D2 may be greater than the length of each source/drain region 108 in the second direction D2 (see FIG. 1A). For example, the deposition process used to form the spacers 124 may be simplified and costs associated therewith may be reduced by respectively forming the spacers 124 on the lower surfaces of the gate structures 102 (e.g., on the lower surfaces of the gate electrodes 112) along substantially all of their length in the second direction D2.

Referring to FIGS. 2 and 3E, a substrate 101 may be formed on the placeholders 126, the transistor structures TS, and the spacers 124 (Block 250 in FIG. 2). For example, the substrate 101 (which may also be referred to as a backside insulating layer or a second substrate) may be formed by a deposition process. In some embodiments, the substrate 101 may include or may be formed of insulating material(s) (e.g., silicon oxide, silicon oxynitride, silicon nitride, silicon carbonitride, silicon boron nitride and/or a low-k dielectric material). For example, a dielectric or insulating material (e.g., an oxide material) may be formed on the placeholders 126, the transistor structures TS (including the gate structures 102, the channel structures 104, and the source/drain regions 108), and the spacers 124 to form the substrate 101. The spacers 124 may have an etch selectivity with respect to the substrate 101. For example, the spacers 124 may include a different material from the substrate 101. The substrate 101 may have the upper surface (or the frontside) S1 and the lower surface (or the backside) S2. The upper surface S1 may face the transistor structures TS, and the lower surface S2 may be opposite to the upper surface S1 in the third direction D3. The spacers 124 and the placeholders 126 may be in the substrate 101 after the substrate 101 is formed. For example, the substrate 101 may at least partially surround the spacers 124 and the placeholders 126 and may be on side surfaces and lower surfaces of the spacers 124 and the placeholders 126. As used herein, “an element A is in an element B” (or similar language) means that the element A is at least partially in the element B but does not necessarily mean that the element A is completely enclosed by the element B.

Referring to FIGS. 2 and 3F, a hard mask pattern 154 may be formed on the substrate 101 (Block 260 in FIG. 2). For example, the hard mask pattern 154 may be formed on the lower surface (or backside) S2 of the substrate 101. In some embodiments, the hard mask pattern 154 may include a multilayer stack of a first mask layer 156 and a second mask layer 158 on the first mask layer 156. In some embodiments, the hard mask pattern 154 may include a different material from the substrate 101. For example, the hard mask pattern 154 may include a carbon material, although embodiments are not limited thereto.

Referring to FIGS. 2 and 3G, first openings 162 may be formed in the substrate 101 (Block 270 in FIG. 2). For example, the hard mask pattern 154 and the lower surface (or backside) S2 of the substrate 101 may be patterned (e.g., lithographically) to define the first openings 162 therein. The first openings 162 may expose some of the placeholders 126. Others of the placeholders 126 may not be exposed by the first openings 162. In some embodiments, an etching process (which may also be referred to as a backside etching process) may be performed to pattern the hard mask pattern 154 formed on the lower surface (or backside) S2 of the substrate 101, and to pattern portions of the substrate 101 exposed by the patterned hard mask pattern 154. For example, the backside etching process may first remove selected portions of the hard mask pattern 154 and then may continue into the underlying substrate 101 to pattern (i.e., form) the first openings 162 therein that expose respective ones of the placeholders 126. In some embodiments, the backside etching process may be a carbon-based etching process, although the present disclosure is not limited thereto. The first opening 162 in the substrate 101 (which exposes the placeholder 126) may define the shape of a lower portion 106-L of a backside contact structure 106 (see FIG. 1B) that is formed in subsequent operations. Each first opening 162 may overlap at least one of the spacers 124 in the third direction D3.

The spacers 124 adjacent to the placeholders 126 may act as etch stops during the backside etching process. For example, the spacers 124 may have an etch selectivity (i.e., may exhibit etch selectivity) with respect to the substrate 101 and the placeholders 126, allowing for portions of the substrate 101 and the placeholders 126 to be removed without removing the spacers 124. The spacers 124 may allow for over-etching of the placeholders 126 (i.e., etching for longer and/or deeper than is typical), while protecting adjacent gate structures 102 from being exposed by the over-etching of the placeholders 126, which may help reduce or prevent the risk of electrical shorts between the gate structures 102 and backside contact structures 106 formed in subsequent operations. For example, the substrate 101 and the first interlayer 122 may include a same material (e.g., an oxide material such as silicon oxide), and thus without the spacers 124, the over-etching of the placeholders 126 may expose the gate structures 102. In some other embodiments, the first interlayer 122 may be omitted, and the spacers 124 may be formed directly on the gate structures 102 (e.g., directly on the gate insulators 114).

As shown in FIG. 3G, the placeholders 126 that are exposed by the first openings 162 may have portions thereof (e.g., lower portions thereof) that are removed during the backside etching process by the over-etching. The over-etching of the placeholder 126 may help ensure that a surface of the placeholder 126 opposite the transistor structures TS is fully exposed by the backside etching process. A thickness of the spacer 124 (e.g., in the third direction D3) may be less than a thickness of the placeholder 126 (e.g., in the third direction D3) to allow for over-etching of the placeholder 126.

FIG. 3H illustrates another example of the backside etching process described above to help illustrate example embodiments of the present disclosure. As shown in FIG. 3H, overlay inaccuracies (i.e., poor overlay) may sometimes occur during the backside etching process used to form first openings 162’ in the substrate 101. As a result, the first openings 162’ formed in the substrate 101 may be misaligned with the placeholders 126. This may lead to only partial exposure of the placeholders 126 or no exposure of the placeholders 126 by the first openings 162’, unless over-etching of the placeholders 126 is performed. As shown in FIG. 3H, the spacers 124 adjacent to the placeholders 126 may act as etch stops during the backside etching process and may allow for over-etching of the placeholders 126, while protecting adjacent gate structures 102 from being exposed by the over-etching. The over-etching of the placeholder 126 may help ensure that a surface of the placeholder 126 opposite the transistor structures TS is fully exposed by the backside etching process.

FIGS. 3I-K illustrate operations in a method of forming an integrated circuit device that follow the operation described above with reference to FIG. 3G. It will be understood, however, that the operations described below with reference to FIGS. 3I-K are also applicable to, and may follow in some other embodiments, the operation described above with reference to FIG. 3H, in which overlay inaccuracies occur during the backside etching process.

Referring to FIGS. 2 and 3I, second openings 164 may be formed in the substrate 101 by removing respective ones of the placeholders 126 (Block 280 in FIG. 2). In some embodiments, the placeholders 126 may be selectively removed, for example, using a selective etching process (e.g., a wet etching process) in the first openings 162, thereby forming the second openings 164 in the substrate 101. The second openings 164 may expose some of the source/drain regions 108 between adjacent gate structures 102. For example, the second openings 164 may be between the first openings 162 and the source/drain regions 108 (e.g., in the third direction D3). The etching process to remove the placeholders 126 may be selective to the material of the source/drain regions 108. Further, the etching process to remove the placeholders 126 may be selective to the material of the substrate 101 and the spacers 124. For example, respective ones of the placeholders 126 may be selectively removed without removing the spacers 124 and the source/drain regions 108. In some embodiments, the hard mask pattern 154 may be removed after the second openings 164 are formed. In some other embodiments, the hard mask pattern 154 may be removed before the second openings 164 are formed.

The second opening 164 in the substrate 101 (which exposes the source/drain region 108) may define the shape of an upper portion 106-U of a backside contact structure 106 (see FIG. 1B) that is formed in subsequent operations. For example, a shape of the second opening 164 may correspond to a shape of the placeholder 126 that was removed. A thickness (or height) of the second opening 164 (e.g., in the third direction D3) may be less than that of the remaining placeholders 126, since the removed placeholders 126 were over-etched in the operation described above with reference to FIG. 3G. As a result, a thickness of an upper portion 106-U of a backside contact structure 106 (see FIG. 1B) may be less than that of the remaining placeholders 126. Respective sidewalls of the second openings 164 may have different slopes than respective sidewalls of the first openings 162. In some embodiments, a step difference may be defined between the respective sidewalls of the second openings 164 (formed by removing respective ones of the placeholders 126) and the first openings 162 (formed by patterning the substrate 101 to expose the placeholders 126). For example, a width in the first direction D1 (e.g., a maximum width in the first direction D1) of the first opening 162 may be greater than (i.e., wider than) a width in the first direction D1 (e.g., a maximum width in the first direction D1) of the second opening 164.

Referring to FIGS. 2, 3J, and 3K, backside contact structures 106 may be formed in the first and second openings 162, 164 in the substrate 101 (Block 290 in FIG. 2). As shown in FIG. 3J, a contact metal layer 172 may be formed (e.g., deposited) on the lower surface (or backside) S2 of the substrate 101, (at least partially) filling the first and second openings 162, 164 therein to contact the source/drain regions 108 exposed by the openings. In some embodiments, a conductive layer (shown by a dashed line in FIG. 3J) that comprises a metal silicide layer (e.g., tungsten silicide, aluminum silicide, and/or copper silicide), a metal nitride layer (e.g., titanium nitride, tantalum nitride, and/or tungsten nitride), or a combination thereof may be formed on (e.g., directly on) a respective source/drain region 108 prior to the contact metal layer 172 being formed on the lower surface (or backside) S2 of the substrate 101. As used herein, the conductive layer may be considered as part of the contact metal layer 172. In some other embodiments, the conductive layer may be omitted. The contact metal layer 172 may overlap the spacers 124 in the third direction D3. As shown in FIG. 3K, a planarization process (e.g., CMP) may be performed on the contact metal layer 172 to form the backside contact structures 106. For example, a material of the substrate 101 may be used as a stop layer during the planarization process. Some of the source/drain regions 108 may contact (e.g., may overlap in the third direction D3) the backside contact structures 106. Others of the source/drain regions 108 may not contact (e.g., may not overlap in the third direction D3) the backside contact structures 106.

Referring back to FIG. 1B, the BSPDN structure 140 (including the backside power rail(s) 144, the backside insulator 142, and associated conductive plugs) may be formed by patterning the backside insulator 142 and forming the backside power rail(s) 144 therein, with the backside contact structure 106 providing electrical connection between the source/drain region 108 and the BSPDN structure 140. The BSPDN structure 140 may be formed on the lower surface (or backside) S2 of the substrate 101. For example, the BSPDN structure 140 may be formed on the substrate 101 opposite the transistor structures TS. Further, the carrier wafer 121 may be turned over, so that the structure of the integrated circuit device 100 shown in FIG. 3K is turned over (i.e., inverted in the third direction D3), and the carrier wafer 121 may be removed. Accordingly, the integrated circuit device 100 shown in FIG. 1B may be formed.

Pursuant to example embodiments herein, integrated circuit devices are provided that include backside contact structures formed in a double self-aligned manner based on spacers and placeholders of different materials. The spacers may function as etch stop layers that allow for over-etching of the placeholders, while protecting adjacent gate structures from being exposed by the over-etching, to thereby prevent electrical shorts between the backside contact structures and the gate structures. The over-etching of the placeholders may help ensure that openings are aligned with source/drain regions, so that the backside contact structures subsequently formed in the openings are self-aligned with the source/drain regions and make reliable electrical contact with the source/drain regions, thereby improving the performance and reliability of the integrated circuit devices.

Unless otherwise defined, all terms used herein have the same meaning as commonly understood by one of ordinary skill in the art. Further, all terms should be interpreted as having a meaning that is consistent with their meaning in the context of the relevant art and this disclosure and will not be interpreted in an idealized or overly formal sense unless expressly so defined herein.

In the description above, example embodiments may be described with reference to regions of particular conductivity types. It will be appreciated that opposite conductivity type devices may be formed by simply reversing the conductivity of the n-type and p-type layers in each of the above embodiments. Thus, it will be appreciated that the present disclosure covers both n-channel and p-channel devices for each different device structure.

The terminology used herein is for the purpose of describing particular embodiments only and is not intended to be limiting of embodiments. The singular forms “a,” “an,” and “the” are intended to include the plural forms as well, unless the context clearly indicates otherwise. The terms “comprises,” “comprising,” “includes” and/or “including” specify the presence of the stated features, steps, operations, elements, components and/or groups, but do not preclude the presence or addition of one or more other features, steps, operations, elements, components and/or groups thereof.

It will be understood that, although the terms “first,” “second,” etc. may be used throughout this specification to describe various elements, these elements should not be limited by these terms. Rather, these terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terms “surround” or “cover” or “fill” as used herein may not require completely surrounding or covering or filling the described elements or layers, but may, for example, refer to partially surrounding or covering or filling the described elements or layers. Components or layers described with reference to “overlap” in a particular direction may be at least partially obstructed by one another when viewed along a line extending in the particular direction or in a plane perpendicular to the particular direction.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. The term “connected” may include physical and/or electrical connections.

Spatially relative terms such as “below” or “above” or “upper” or “lower” or “top” or “bottom” or “side” may be used herein to describe a relationship of one element, layer or region to another element, layer or region based on a frame of reference (e.g., a substrate), as illustrated in the figures. It will be understood that these terms are intended to encompass different orientations of the device in addition to the orientation depicted in the figures.

Example embodiments are described herein with reference to the accompanying drawings, which may include cross-section illustrations that are schematic illustrations of idealized embodiments (and intermediate structures). Many different forms and embodiments are possible without deviating from the teachings of this disclosure. Accordingly, the present disclosure should not be construed as limited to the example embodiments set forth herein. As such, it will be understood by those of ordinary skill in the art that various changes in form and details may be made therein without departing from the scope as defined herein. In the drawings, the sizes and relative sizes of layers and regions may be exaggerated for clarity. Additionally, variations from the shapes of the illustrations as a result, for example, of manufacturing techniques and/or tolerances, are to be expected.

Embodiments of the present disclosure are also described with reference to fabrication operations and flowchart diagrams. It will be appreciated that the steps shown in the fabrication operations and flowchart diagrams need not be performed in the order shown.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope is to be determined by the broadest permissible interpretation of the following claims and their equivalents, and shall not be restricted or limited by the foregoing detailed description.

1. An integrated circuit device, comprising:
a substrate;
a source/drain region on the substrate;
a gate structure on the substrate and adjacent to the source/drain region;
a backside contact structure extending in the substrate and electrically connected to the source/drain region; and
a spacer in the substrate and on a lower surface of the gate structure, the spacer adjacent to the backside contact structure.

2. The integrated circuit device of claim 1, wherein the spacer overlaps the backside contact structure in a direction perpendicular to an upper surface of the substrate, and is between the backside contact structure and the gate structure.

3. The integrated circuit device of claim 1, wherein the spacer comprises a nitride material, and
wherein the substrate comprises a material that is different from the nitride material.

4. The integrated circuit device of claim 1, wherein the gate structure is adjacent to the source/drain region in a first direction parallel to an upper surface of the substrate, and extends in a second direction parallel to the upper surface of the substrate and intersecting the first direction, and
wherein a length of the spacer in the second direction is greater than a length of the source/drain region in the second direction.

5. The integrated circuit device of claim 4, wherein the length of the spacer in the second direction is substantially equal to a length of the gate structure in the second direction.

6. The integrated circuit device of claim 1, wherein a lower surface of the spacer is convex toward a lower surface of the substrate.

7. The integrated circuit device of claim 1, wherein the source/drain region is free of overlap with the spacer in a direction perpendicular to an upper surface of the substrate.

8. The integrated circuit device of claim 1, wherein the source/drain region is a first source/drain region, and
wherein the integrated circuit device further comprises:
a second source/drain region spaced apart from the first source/drain region, with the gate structure therebetween; and
a placeholder in the substrate and on a lower surface of the second source/drain region.

9. The integrated circuit device of claim 8, wherein a thickness of the spacer in a direction perpendicular to an upper surface of the substrate is less than a thickness of the placeholder in the direction.

10. The integrated circuit device of claim 8, wherein the spacer is between the placeholder and the backside contact structure in a direction parallel to an upper surface of the substrate, and
wherein the placeholder comprises a first material, and the spacer comprises a second material that is different from the first material.

11. The integrated circuit device of claim 1, further comprising a channel structure at least partially surrounded by the gate structure and electrically connected to the source/drain region, the channel structure comprising one or more channel regions spaced apart in a direction perpendicular to an upper surface of the substrate,
wherein the channel structure overlaps the spacer in the direction.

12. The integrated circuit device of claim 1, further comprising a backside power delivery network (BSPDN) structure on a lower surface of the substrate,
wherein the backside contact structure electrically connects the BSPDN structure to the source/drain region.

13. A method of forming an integrated circuit device, the method comprising:
forming a transistor structure, the transistor structure comprising a source/drain region and a gate structure adjacent to the source/drain region;
forming a spacer on the gate structure;
forming a substrate on the spacer such that the spacer is in the substrate; and
forming a backside contact structure in the substrate, the backside contact structure electrically connected to the source/drain region, overlapping the source/drain region in a direction perpendicular to an upper surface of the substrate, and adjacent to the spacer.

14. The method of claim 13, wherein forming the spacer comprises selectively depositing the spacer on the gate structure using at least one of a chemical vapor deposition (CVD) process or an atomic layer deposition (ALD) process.

15. The method of claim 13, further comprising selectively removing a placeholder in the substrate to form an opening in the substrate,
wherein forming the backside contact structure in the substrate comprises forming the backside contact structure in the opening.

16. The method of claim 15, wherein the placeholder comprises a different material from the substrate and the spacer.

17. The method of claim 13, further comprising forming a backside power delivery network (BSPDN) structure on the substrate opposite the transistor structure,
wherein the backside contact structure is electrically connected to the BSPDN structure and extends in the substrate between the source/drain region and the BSPDN structure.

18. A method of forming an integrated circuit device, the method comprising:
forming a placeholder in a first substrate;
forming a transistor structure on the first substrate, the transistor structure comprising a source/drain region on the placeholder and a gate structure adjacent to the source/drain region;
selectively removing the first substrate from around the placeholder;
forming a spacer on the gate structure and adjacent to the placeholder;
forming a second substrate on the spacer and the placeholder such that the spacer and the placeholder are in the second substrate;
forming a first opening in the second substrate to expose the placeholder;
forming a second opening in the second substrate by selectively removing the placeholder exposed by the first opening; and
forming a backside contact structure in the first and second openings in the second substrate, the backside contact structure electrically connected to the source/drain region and overlapping the source/drain region in a direction perpendicular to an upper surface of the second substrate.

19. The method of claim 18, wherein forming the first opening in the second substrate comprises removing a portion of the placeholder, and
wherein forming the second opening in the second substrate comprises selectively removing the placeholder without removing the spacer.

20. The method of claim 18, wherein forming the spacer comprises selectively depositing the spacer on the gate structure using at least one of a chemical vapor deposition (CVD) process or an atomic layer deposition (ALD) process.
